(19) United States
(12) Patent Application Publication
(10) Pub. No.: US 2025/0112077 A1
(43) Pub. Date: Apr. 3, 2025

(54) ARCHITECTURES FOR FACILITATING BONDING IN WAFER-LEVEL SELECTIVE TRANSFERS

(71) Applicant: Intel Corporation, Santa Clara, CA (US)

(72) Inventors: Feras Eid, Chandler, AZ (US); Andrey Vyatskikh, Hillsboro, OR (US); Adel Elsherbini, Chandler, AZ (US); Brandon M. Rawlings, Chandler, AZ (US); Tushar Kanti Talukdar, Wilsonville, OR (US); Thomas L. Sounart, Chandler, AZ (US); Kimin Jun, Portland, OR (US); Johanna Swan, Scottsdale, AZ (US); Grant M. Kloster, Lake Oswego, OR (US); Carlos Bedoya Arroyave, Portland, OR (US)

(73) Assignee: Intel Corporation, Santa Clara, CA (US)

(21) Appl. No.: 18/478,391

(22) Filed: Sep. 29, 2023

(51) Int. Cl. H01L 21/683; H01L 23/00; H01L 23/538

(52) U.S. Cl. CPC H01L 21/6835; H01L 23/5383; H01L 24/08; H01L 24/80; H01L 2221/68368; H01L 2224/08121; H01L 2224/08225; H01L 2224/80006; H01L 2224/80895; H01L 2224/80896; H01L 2924/10156

(57) ABSTRACT

An embodiment discloses an electronic device comprising an integrated circuit (IC) die, a stub extending from the IC die; and a mesa structure under the IC die, wherein the IC die and the stub are bonded to the mesa structure.

### BACKGROUND

In semiconductor manufacturing, layer transfer techniques are used to transfer a layer from one substrate to another, typically at wafer-level scale. These techniques require a full layer to be transferred in its entirety regardless of whether the entire layer is needed. As a result, any unneeded portions of a transferred layer must be etched off after the transfer, which increases costs and process complexity.

### BRIEF DESCRIPTION OF THE DRAWINGS

FIGS. 1A-I illustrate an example process flow for selective layer transfers using selective release techniques.

FIGS. 2A-I illustrate an example process flow for selective layer transfers using a blanket laser exposure.

FIGS. 3A-I illustrate an example process flow for selective layer transfers from a singulated donor substrate.

FIGS. 4A-C illustrate an example process flow for selective layer transfers from multiple donor substrates.

FIGS. 5A-F illustrate an example process flow for forming an integrated circuit package using a selective transfer of a passive interposer.

FIGS. 6A-B illustrate an example of a selective layer transfer between wafers.

FIG. 7 illustrates a flowchart for performing selective layer transfers.

FIGS. 8A-C illustrate wafers with strips to facilitate bonding in wafer-level selective transfers.

FIG. 9 illustrates a wafer with tethers between dies to facilitate bonding in wafer-level selective transfers.

FIG. 10 illustrates a wafer with tethers in orthogonal directions between dies to facilitate bonding in wafer-level selective transfers.

FIG. 11 illustrates a wafer with diagonally oriented tethers between dies to facilitate bonding in wafer-level selective transfers.

FIG. 12 illustrates tethers between dies with chamfered corners to facilitate bonding in wafer-level selective transfers.

FIGS. 13A-B illustrate a wafer with tethered dies and a singulated die with tether stubs.

FIG. 14 illustrates a flowchart for performing selective layer transfers using bonding features of a donor substrate.

FIG. 15 illustrates a top view of a wafer and dies that may be included in a microelectronic assembly.

FIG. 16 illustrates a cross-sectional side view of an integrated circuit device that may be included in a microelectronic assembly.

FIGS. 17A-D illustrate perspective views of example planar, FinFET, gate-all-around, and stacked gate-all-around transistors.

FIG. 18 illustrates a cross-sectional side view of an integrated circuit device assembly that may include a microelectronic assembly.

FIG. 19 illustrates a block diagram of an example electrical device that may include a microelectronic assembly.

### DETAILED DESCRIPTION

### Selective Layer Transfer

In semiconductor manufacturing, layer transfer techniques are used to transfer a layer from one substrate to another, typically at wafer-level scale. Layer transfers are useful for a variety of applications in semiconductor manufacturing, including two-dimensional (2D) material fabrication, Group III-V semiconductors over complementary metal-oxide semiconductors (CMOS), and traditional CMOS applications such as metal-insulator-metal (MIM) devices and thin device and/or interconnect layer transfers. Current layer transfer techniques are limited to full layer transfers, however, which may impact cost and performance when the full layer is not needed. For example, blanket layer transfer techniques, such as ion-cut and laser debonding layer transfers, require a full layer to be transferred in its entirety. As a result, any unneeded areas of the transferred layer must be etched off after the transfer, which results in added cost and process complexity.

Alternatively, pick-and-place techniques can be used to transfer specific dies or chiplets. For example, a chiplet generally refers to an integrated circuit (IC) that contains a well-defined subset of functionality, which is designed to be combined with other chiplets to form a single IC package. To transfer chiplets (e.g., for MIM chiplet integration in a system-on-a-chip (SoC)), chiplet devices are fabricated on a donor substrate (e.g., a wafer or panel), the donor substrate is singulated into chiplets, and the chiplets are then individually attached to a receiver substrate (e.g., an SoC wafer or package) using pick-and-place machines. This adds significant cost due to the extra processing required to singulate the wafer and individually attach the respective chiplet dies. For example, chiplets are generally manufactured on relatively thick substrates to enable them to be handled during the singulation and attach steps without being damaged, and after the attach step, additional processing is performed to thin the chiplets and/or remove the carrier substrate, which further increases the cost and process complexity. In particular, chiplets are typically manufactured on substrates that are over 700 micrometers (m or microns) thick to provide structural and mechanical stability during fabrication, and after the singulation/attach steps, they may be thinned to approximately 20-100 m by grinding the backside. However, grinding typically causes chipping along the edges of the chiplet dies. Further, it can be challenging to thin chiplets beyond 20 m without producing defects. Similarly, chiplets are typically singulated with a die area on the millimeter level scale, as pick-and-place assembly becomes very challenging for chiplets smaller than 1 millimeter (mm)².

Integrated circuits can also be manufactured monolithically, where all IC components and interconnections are fabricated sequentially on the same underlying substrate or wafer. Monolithic ICs have various limitations, however, including design limitations due to incompatible processes, lack of flexibility, and low yield.

Accordingly, this disclosure presents selective layer transfer techniques for selectively transferring portions of a layer between substrates, along with devices and systems formed using the same. For example, one or more of the described techniques enable select areas on a donor substrate to be transferred to a receiver substrate, which enables the donor substrate to be reused multiple times, while also addressing the limitations described above for blanket layer transfers and pick and place techniques. In particular, the described solution (e.g., one or more of the embodiments described herein) uses a selective release technology on a donor substrate (e.g., wafer, panel, or die) in conjunction with a patterned bonding template on a receiver substrate (e.g., wafer, panel, or die) to allow select areas of a layer on the donor substrate to be transferred to the receiver substrate. For purposes of this disclosure, the term layer may sometimes be used to refer to a single layer of a single material or multiple layers of one or more materials. For example, a selective transfer layer may be formed on a substrate, and may be an individual layer of material, or a stack of layers that collectively form a layer of IC components (e.g., dies, interconnects, bridges, capacitors, and/or other semiconductor devices). A layer may also include stacked wafers, such as wafer-to-wafer bonded and stacked logic and/or memory wafers. As an example, a donor wafer may include a layer of IC components (e.g., IC dies), and a selective layer transfer may be used to selectively and simultaneously transfer a specific subset of those IC components to a receiver wafer.

The described solution provides various advantages. For example, the described solution enables select areas of a donor wafer to be transferred as opposed to an entire layer, which enables the donor wafer to be reused for multiple products, thus amortizing the cost of expensive devices (e.g., high-density MIM capacitors or high-density passive interposers) across multiple wafers. This solution also eliminates the need to etch away superfluous areas as required by full layer transfers (and as a result, unlike the etched areas after a full layer transfer, selectively transferred areas may not have tapered edges from etching or may have reversed tapering due to the etch to singulate before transfer).

Further, in various examples, layers of IC components can be selectively transferred at any suitable level of granularity, including full IC dies and packages, interconnects, transistors, resistors, capacitors, partial layers or layer stacks, etc.

This solution also enables areas of ultra-thin layers to be selectively transferred without the added processing and yield loss resulting from the handling challenges of chiplet pick-and-place methods (e.g., singulation, individually attaching each chiplet, post-attach thinning of chiplets). This helps reduce the Z-height of a product (e.g., for form factor, thermal, and/or power delivery reasons) as well as the overall process complexity. For example, very thin IC dies or chiplets can be formed on any substrate and selectively transferred directly from that substrate. As a result, selectively transferring the dies not only eliminates the need for post-attach thinning, it also enables the dies to be much thinner than dies that are singulated, pick-and-place attached, and then subsequently thinned. In some cases, for example, the described solution may enable transfers of dies with thicknesses ranging from 100 nanometers (nm) to 5 μm or more. Further, since no post-attach thinning is needed, the selectively transferred dies may have no or minimal chipping on the die edges since no grinding is performed, unlike chiplets that are thinned after attachment.

Similarly, the described solution supports selective transfers of very small areas on a donor substrate, such as very small dies or chiplets, which is extremely challenging using pick-and-place techniques. In some cases, for example, the described solution may enable transfers of dies (or other IC components) with an area less than 1 mm², such as 100 μm² (10×10 m), 10,000 μm² (100×100 m), 810,000 μm² (900×900 m), etc. (with no limits on the maximum size of an area that can be selectively transferred).

This solution also supports selective transfers of dies with non-standard shapes and designs that are difficult to handle using pick-and-place machines, such as dies with atypical, arbitrary, irregular, or non-convex shapes (e.g., L shape, U shape, shapes with acute angles), dies with high aspect ratios (e.g., 8:1 aspect ratio or higher), dies with holes, and so forth.

Further, this solution has very low topography and supports high surface cleanliness and planarization (e.g., using chemical mechanical polishing (CMP) processing), which makes it compatible with hybrid bonding and fusion bonding processing. Additional advantages are described throughout this disclosure and apparent from the description below.

Accordingly, this solution enables complex IC packages and products to be manufactured by selectively transferring certain components (e.g., active circuitry such as IC dies, passive circuitry) instead of incorporating them using traditional processes, such as: (i) full layer transfers with superfluous areas etched away; (ii) pick-and-place assembly of individual IC components; and/or (iii) monolithic IC fabrication.

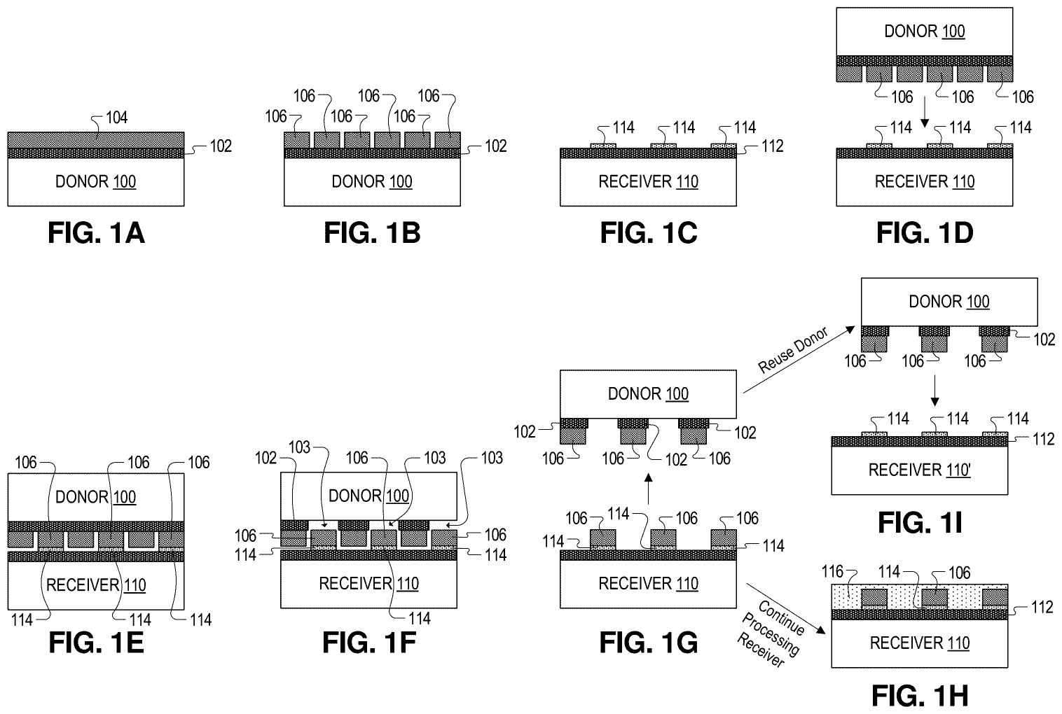

FIGS. 1A-I illustrate an example process flow for selective layer transfers using selective release techniques. In the illustrated example, a layer of integrated circuit (IC) components is selectively transferred from a donor substrate 100 to a receiver substrate 110, as described further below.

In FIG. 1A, a release layer 102 is formed over a carrier substrate, which is referred to as the donor substrate 100. The release layer 102 is a temporary bonding and debonding layer for the layer 104 to be selectively transferred. In some embodiments, the release layer 102 may include one or more layers and/or materials capable of providing adhesion to the donor substrate 100 and/or absorbing energy from a laser (e.g., laser beams), such as lossy dielectric and/or thin metal layer(s) that provide adhesion and absorb/reflect infrared (IR) light, organic polymer layer(s) (e.g., polyimides) that provide adhesion and absorb visible or ultraviolet (UV) light, and/or patterned dielectric layer(s) with anchors to provide residual adhesion (e.g., after the metal layer is ablated by an IR laser).

The layer 104 to be selectively transferred is formed over the release layer 102 on the donor substrate 100, such as by fabricating the layer 104 directly (e.g., over the release layer 102) or blanket transferring the layer 104. The selective transfer layer 104 may include one or more layers of material, such as a single layer of material or a stack of layers that collectively form a layer of IC components (e.g., full IC dies, chiplets, interconnects, bridges, capacitors, transistors, and/or other semiconductor devices). In some embodiments, for example, the selective transfer layer 104 may be a prefabricated semiconductor wafer containing unsingulated integrated circuit (IC) dies, which is blanket transferred to the release layer 102 on a donor substrate 100.

In FIG. 1B, the selective transfer layer 104 is diced over the donor substrate 100—without dicing through the donor substrate 100—to partially singulate the IC components 106 in the layer 104, using techniques such as etching, reactive ion etching (RIE), plasma dicing, mechanical sawing, etc. In some embodiments, the release layer 102 may also be singulated (e.g., diced or etched) along with the transfer layer 104.

In FIG. 1C, a release layer 112 is optionally formed over another carrier substrate, which is referred to as the receiver substrate 110. For example, the release layer 112 may be formed over the receiver substrate 110 if the selectively transferred IC components 106 will be subsequently debonded from the receiver substrate 110 after the transfer. Otherwise, if the selectively transferred IC components 106 will remain on the receiver substrate 110 after the transfer, the release layer 112 on the receiver substrate 110 may be omitted.

Next, a bonding template comprising bonding features 114 is formed on the surface of the receiver substrate 110 (e.g., above the release layer 112, if included). The bonding template includes a pattern of bonding features 114 or adhesive areas that enable specific areas on the donor substrate 100 to be selectively transferred to the receiver substrate 110. For example, the positions of the bonding features 114 or adhesive areas on the receiver substrate 110 correspond to the areas or IC components 106 on the donor substrate 100 that will be transferred to the receiver substrate 110.

In some embodiments, for example, the bonding features 114 may include “island” or “mesa” structures that are similar in size to the target areas to be transferred from the donor substrate 100. For example, each island or mesa structure may be a raised structure on the surface of the receiver substrate 110 with a similar footprint (e.g., shape/surface area) as a corresponding IC component 106 on the donor substrate 100. In other embodiments, the bonding features 114 may be replaced by lithographically or additively manufactured surface treatments that enhance the adhesion in the target areas of the receiver substrate 110 (e.g., the areas where the bonding features 114 are shown) and prevents adhesion in the other areas, including, without limitation, surface topography variations, use of materials with high and/or low adhesion, treatments using hydrophobic materials and/or self-assembled monolayers (SAMs), and/or surface activation techniques, among other examples.

In various embodiments, these bonding features 114 may be made of dielectric materials, conductive materials (e.g., metal), or both, depending on whether electrical connections are needed between the bonded IC components 106 and the receiver substrate 110. For example, the bonding features 114 may be blanket dielectric structures with no electrical contacts, or they may be dielectric structures with electrical contacts through them (e.g., hybrid bonding pads) if electrical connections are needed through the bonding interface.

In FIG. 1D, the donor and receiver substrates 100, 110 are brought into contact with each other with their top surfaces aligned face to face, such that the target IC components 106 on the donor substrate 100 are aligned with corresponding bonding features 114 on the receiver substrate 110.

In FIG. 1E, the donor and receiver substrates 100, 110 are partially bonded together. For example, the areas of the receiver substrate 110 with protruding surface features or “mesas” are bonded to corresponding areas on the donor substrate 100 with the target IC components 106, while other areas of the donor and receiver substrates 100, 110 remain unbonded. In some embodiments, for example, this is controlled through the height of the bonding protrusions (e.g., bonding features 114) to prevent unwanted contact between areas that are not to be transferred. As previously mentioned, this can also be controlled through surface treatment of the different areas to enable good adhesion in the target areas (e.g., where the bonding features 114 are shown) and prevent or reduce adhesion in other areas.

In FIG. 1F, the IC components 106 bonded to the receiver substrate 110 are selectively debonded from the donor substrate 100 using selective release techniques, such as IR debonding, selective visible or ultraviolet (UV) laser exposure, etc. For example, areas 103 of the release layer 102 where those IC components 106 are bonded to the donor substrate 100 may be selectively removed or ablated using a laser, such as an IR or UV laser, which forms gaps or voids in the release layer 102 and causes those IC components 106 to be released from the donor substrate 100.

In FIG. 1G, the donor and receiver substrates 100, 110 are mechanically separated from each other. At this point, the IC components 106 that were selectively bonded to the receiver substrate 110 (e.g., via the bonding features 114) and debonded from the donor substrate 100 remain on the receiver substrate 110 and are separated from the donor substrate 100. All other IC components 106 that were not bonded to the receiver substrate 110 remain on the donor substrate 100.

In FIG. 1H, the receiver substrate 110 is now ready for continued processing, such as dielectric fill 116 around the transferred IC components 106, planarization, selectively transferring or pick-and-place attaching additional IC dies or other IC components, via formation, formation of interconnect/metallization layers, attaching a structural substrate, debonding the receiver substrate (e.g., via the optional receiver release layer 112), and/or any other processing required for the finished product (e.g., an IC package).

In FIG. 1I, the donor substrate 100 is then reused to transfer the remaining IC components 106 (e.g., the remaining areas of the selectively transferred layer 104) to a new receiver substrate 110′. The donor substrate 100 can continue being reused in this manner until all IC components 106, or the entire layer 104, have been selectively transferred to any number of receiver substrates 110.

It should be appreciated that the illustrated process flow for selective layer transfers is merely presented as an example and many other process variations are also possible. For example, the donor and receiver substrates 100, 110 may be wafers, panels, IC packages, chiplets, dies, or any combination thereof (e.g., for transfers from wafer to panel, chiplet to wafer, etc.). Moreover, each substrate 100, 110 may be made of a variety of materials, including, without limitation, inorganic materials such as silicon, silicon on insulator (SOI), quartz, glass, and/or Group III-V materials, organic materials such as IR or UV transparent epoxies, and so forth.

The materials used in the release layers 102, 112 may vary depending on the type of release or debonding technology used. For example, for infrared (IR) laser debonding, the release layers 102, 112 may include one or more materials capable of absorbing and/or reflecting infrared (IR) light, such as a thin metal layer or multiple metal layers (e.g., aluminum (Al), tungsten (W), copper (Cu), titanium (Ti), titanium nitride (TiN), tantalum (Ta), tantalum nitride (TaN)). For ultraviolet (UV) laser debonding, the release layers 102, 112 may include one or more materials capable of absorbing UV light (e.g., a wide range of organic polymers, including, but not limited to, polyimides). In some embodiments, the release layers 102, 112 may additionally or alternatively include one or more layers of dielectric materials (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅)), which may be used to buffer laser ablation and thermal energy, control thin film interference or adhesion, and/or provide residual adhesion after other materials and/or layers in the release layers 102, 112 are weakened, removed, and/or ablated by a laser.

The number of layers 104 on the donor substrate 100, the arrangement/structure of the layers 104, the materials in each layer 104, and the type of IC components 106 formed in those layers 104 may vary.

The adhesive areas or bonding features 114 on the receiver substrate 110 may be formed using any suitable surface treatments or other techniques to control the level of adhesion in different areas, including, without limitation, surface topography variations (e.g., mesas, recesses), use of materials with high and/or low adhesion, treatments using hydrophobic materials and/or self-assembled monolayers (SAMs), and/or surface activation techniques, among other examples. Moreover, the bonding features 114 or adhesive areas on the receiver substrate 110 may vary in size, shape, height, topography, pattern, and materials. For example, the bonding features 114 may be formed using inorganic dielectrics such as silicon dioxide (SiO₂), silicon nitride (Si₃N₄), silicon oxy nitride (SiON), and/or silicon carbon nitride (SiCN), organic dielectrics such as photoresists and adhesives, conductive materials such as metals, and combinations thereof.

The donor and receiver substrates 100, 110 may be (partially) bonded using any suitable bonding techniques, including, without limitation, hybrid bonding, fusion bonding, and adhesive bonding. The donor and receiver substrates 100, 110 may be debonded or released using any suitable debonding techniques, including, without limitation, IR and UV laser debonding. Further, there may be additional cleaning steps to reuse the donor substrate 100 before or after each selective layer transfer to a receiver substrate 110.

Further, in some embodiments, additional bonding and/or alignment features may be included at the wafer level and/or die level (e.g., on the donor dies, donor wafer, receiver wafer, and/or final product). For example, the donor and/or receiver wafer may include ridge or cross structures to facilitate bonding, such as a single ridge (e.g., a line or strip of dielectric material) extending across and/or through the center of the wafer, or multiple orthogonal ridges forming a cross-like pattern. Alignment features for wafers, die-lets, and/or die arrays may also be included to facilitate bonds with proper alignment. Further, multiple dies may be connected by small (e.g., dielectric) bridges to help them collectively bond and transfer together. For example, if some of the bridge-connected dies successfully bond to the receiver, the bridges may help others bond as well. Thus, these inter-die bridges may be present on the donor before the transfer, and on the receiver and final product after the transfer.

Further, in some cases, the debonding process may cause some unique damage or delamination near the edge and/or on the back of the dies, which does not impact process performance but may be indicative of this solution being used.

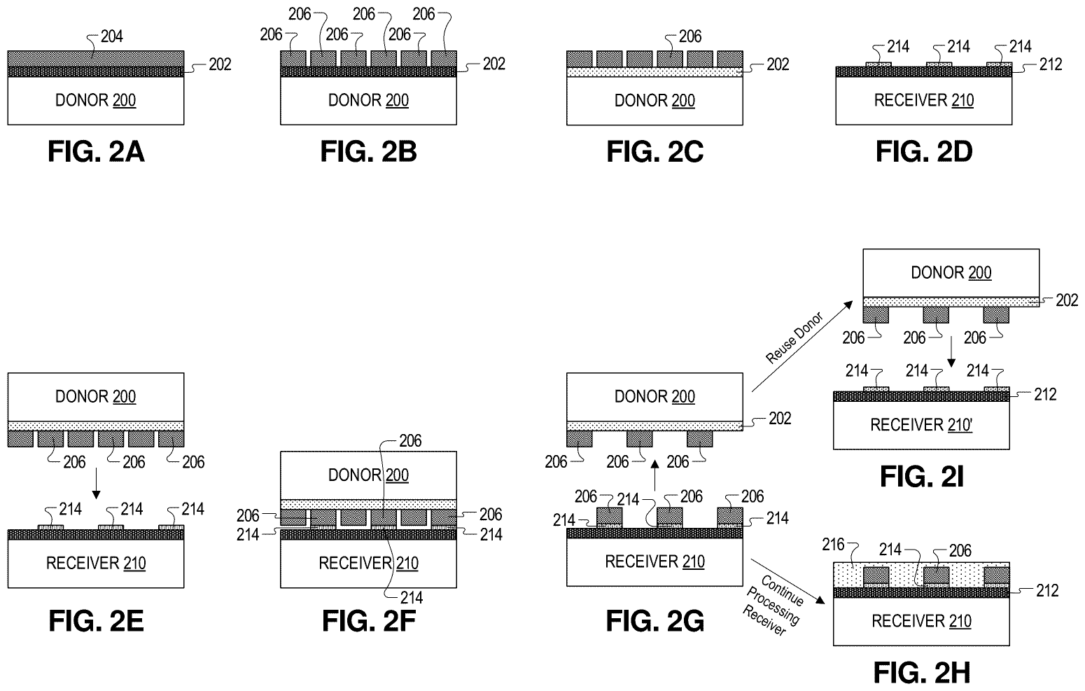

FIGS. 2A-I illustrate an example process flow for selective layer transfers using a blanket laser exposure. In the illustrated example, a layer 204 of integrated circuit (IC) components 206 is selectively transferred from a donor substrate 200 to a receiver substrate 210. Prior to the transfer, however, the entire release layer 202 on the donor 200 is mechanically weakened (e.g., using IR laser, visible light laser, UV laser, chemical etching, and/or thermal techniques), which may also be referred to as a partial release. In this manner, after the target IC components 206 on the donor 200 are bonded to the receiver 210, they can be fully released from the donor 200 by mechanically separating the donor 200 from the receiver 210. In some cases, this may result in a simplified and faster bond/debond flow compared to the bond/selective release/debond flow of FIGS. 1A-I. Other variations of this flow are described in connection with other FIGS. herein. Alternatively, rather than using blanket laser exposure, the respective materials used in the donor release layer 202 and the receiver bonding template 214 may be selected such that the bond to the donor 200 is weaker than the subsequently formed bond to the receiver 210.

In FIG. 2A, a release layer 202 is formed over a donor substrate 200. The layer 204 to be selectively transferred is formed over the release layer 202, such as by fabricating the layer 204 directly (e.g., over the release layer 202) or blanket transferring the layer 204. In some embodiments, the selective transfer layer 204 may be a layer of IC components (e.g., IC dies, chiplets, interconnects, bridges, capacitors, transistors, and/or other semiconductor devices).

In FIG. 2B, the selective transfer layer 204 is diced over the donor substrate 200—without dicing through the entire donor substrate 200—to partially singulate the IC components 206 in the layer 204.

In FIG. 2C, blanket laser exposure is performed on the donor release layer 202 to weaken the entire release layer 202 prior to the transfer. In some embodiments, for example, blanket laser exposure may be performed using laser (e.g., IR or UV laser exposure), chemical, and/or thermal techniques. In this manner, the weakened release layer 202 has lower bond energy, which results in a partial release of the IC components 206 bonded to that layer 202.

In FIG. 2D, a release layer 212 is optionally formed over a receiver substrate 210. For example, if the selectively transferred IC components 206 will be subsequently debonded from the receiver substrate 210 after the transfer, a release layer 212 may be formed over the receiver 210; otherwise, the release layer 212 on the receiver 210 may be omitted.

Next, a bonding template 214 is formed on the surface of the receiver substrate 210 (e.g., above the release layer 212, if included). The bonding template 214 includes a pattern of bonding features or adhesive areas, such as mesas, that enable specific areas on the donor substrate 200 to be selectively transferred to the receiver substrate 210. In various embodiments, however, any suitable surface treatments or other techniques may be used to control the level of adhesion on different areas of the receiver substrate 210 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples.

In FIG. 2E, the donor and receiver substrates 200, 210 are brought into contact with each other with their top surfaces aligned face to face, such that the target IC components 206 on the donor 200 are aligned with corresponding bonding features of bonding template 214 on the receiver 210.

In FIG. 2F, the donor and receiver substrates 200, 210 are partially bonded together, where the areas of the donor 200 with the target IC components 206 are bonded to the areas on the receiver 210 with bonding mesas of bonding template 214.

In FIG. 2G, the donor and receiver substrates 200, 210 are mechanically separated from each other. At this point, the IC components 206 that were selectively bonded to the receiver 210 (e.g., via the bonding mesas of bonding template 214) remain on the receiver 210 and are debonded/separated from the donor 200 due to the blanket weakening of the donor release layer 202. All other IC components 206 that were not bonded to the receiver 210 remain on the donor 200.

Alternatively, in some embodiments, instead of (or in addition to) performing blanket laser exposure in FIG. 2C, the respective materials used in the donor release layer 202 and the receiver bonding template 214 may be selected such that the target IC components 206 will have a stronger bond to the receiver 210 than the donor 200. In this manner, when the donor 200 and receiver 210 are mechanically separated, the target IC components 206 will debond from the donor 200 and remain on the receiver 210 due to the disparity in bond strength.

In FIG. 2H, the receiver substrate 210 is ready for continued processing, such as dielectric fill 216 around the transferred IC components 206, planarization, selectively transferring or pick-and-place attaching additional IC dies or other IC components, via formation, formation of interconnect/metallization layers, attaching a structural substrate, debonding the receiver substrate (e.g., via the optional receiver release layer 212), and/or any other processing required for the finished product (e.g., an IC package).

In FIG. 2I, the donor substrate 200 is then reused to transfer the remaining IC components 206 (e.g., the remaining areas of the selectively transferred layer 204) to a new receiver substrate 210′. The donor substrate 200 can continue being reused in this manner until all IC components 206, or the entire layer 204, have been selectively transferred to any number of receiver substrates 210.

Elements labeled with reference numerals in FIGS. 2A-I may be similar to those having similar reference numerals in FIGS. 1A-I. Further, it should be appreciated that the illustrated process flow for selective layer transfers is merely presented as an example and many other process variations are also possible, including, but not limited to, the process variations described throughout this disclosure.

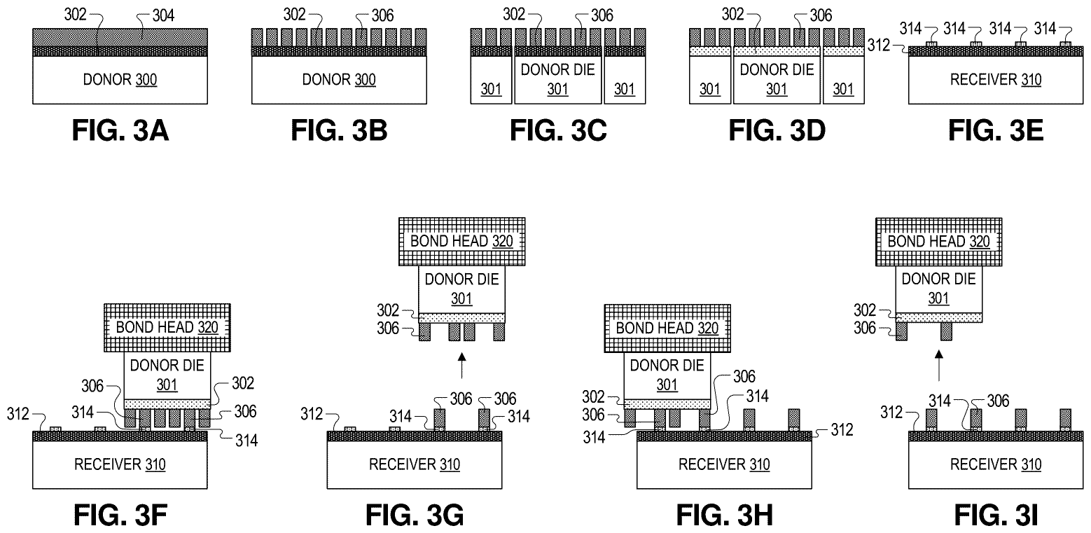

FIGS. 3A-I illustrate an example process flow for selective layer transfers from a singulated donor substrate 300. In some cases, for example, if the percentage of transferred integrated circuit (IC) components 306 is relatively small for each selective layer transfer, it may be easier and more cost efficient to dice the donor substrate 300 and perform the transfers from singulated donor dies 301 that contain smaller subsets of IC components 306 from the original donor substrate 300. Accordingly, in the illustrated example, a donor substrate 300 with a layer 304 of IC components 306 is diced, and the resulting layer of IC components 306 on a singulated donor die 301 is selectively transferred to a receiver substrate 310. In this manner, the transfers are performed at the donor die level rather than the wafer or panel level.

In FIG. 3A, a release layer 302 is formed over a donor substrate 300. The layer 304 to be selectively transferred is formed over the release layer 302, such as by fabricating the layer 304 directly or blanket transferring the layer 304. In some embodiments, the selective transfer layer 304 may be a layer of IC components (e.g., IC dies, chiplets, interconnects, bridges, capacitors, transistors, and/or other semiconductor devices).

In FIG. 3B, the selective transfer layer 304 is diced over the donor substrate 300—without dicing through the donor substrate 300—to partially singulate the IC components 306 in the layer 304. In some embodiments, the release layer 302 may also be singulated (e.g., diced or etched) along with the transfer layer comprising the IC components 306.

In FIG. 3C, the donor substrate 300 is diced into singulated donor dies 301 that each contain a subset of the IC components 306 from the original donor substrate 300. For example, each donor die 301 may include one or more IC components 306 from the layer 304 on the original donor substrate 300.

In FIG. 3D, either blanket laser exposure (as shown) or a selective laser release is performed on the donor release layer 302 to weaken the entire release layer 302 prior to the transfer (e.g., using IR/UV laser exposure or thermal techniques), thus partially releasing the IC components 306 from the donor dies 301.

In FIG. 3E, a release layer 312 is optionally formed over a receiver substrate 310 (e.g., in the event the selectively transferred IC components 306 will be subsequently debonded from the receiver substrate 310 after the transfer). Next, a bonding template 314 is formed on the surface of the receiver substrate 310 (e.g., above the release layer 312, if included). The bonding template 314 includes a pattern of bonding features or adhesive areas, such as mesas, that enable specific areas of a donor die 301 to be selectively transferred to the receiver substrate 310. In various embodiments, however, any suitable surface treatments or other techniques may be used to control the level of adhesion on different areas of the receiver substrate 310 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples.

In FIG. 3F, a bond head 320 is used to pick up one of the donor dies 301 and place it face down on the receiver substrate 310 such that the target IC components 306 on the donor die 301 are aligned with the corresponding bonding mesas of bonding template 314 on the receiver substrate 310. The donor die 301 and receiver substrate 310 are then partially bonded together (e.g., die-to-wafer bond) with the target IC components 306 bonded to the receiver bonding mesas 314.

In FIG. 3G, the bond head 320 lifts up and mechanically separates the donor die 301 from the receiver substrate 310. At this point, the IC components 306 that were selectively bonded to the receiver 310 (e.g., via the bonding mesas of bonding template 314) remain on the receiver 310 and are debonded/separated from the donor die 301 (e.g., die-to-wafer debond) due to the blanket weakening of the donor release layer 302. All other IC components 306 that were not bonded to the receiver substrate 310 remain on the donor die 301.

Alternatively, in some embodiments, instead of (or in addition to) performing a blanket laser exposure in FIG. 3D, the target IC components 306 may be selectively released (e.g., as described with respect to FIG. 1F), or the donor release layer 302 and receiver bonding template 314 may be formed with materials having different bonding strengths such that the target IC components 306 will have a stronger bond to the receiver substrate 310 than the donor die 301.

In FIG. 3H and FIG. 3I, the bond head 320 steps and repeats. For example, the bond head 320 moves to a new position and repeats the process of FIG. 3F and FIG. 3G, respectively, to selectively transfer another group of IC components 306 from the donor die 301 to other areas of the receiver substrate 310.

The process may repeat in this manner until all IC components 306 on the donor die 301 have been transferred. At that point, the bond head 320 may pick up another donor die 301 and continue transferring IC components 306 from the new donor die 301 to the same or different receiver substrate 310.

After all transfers to the receiver substrate 310 are complete, the receiver 310 may be ready for continued processing, such as dielectric fill around the transferred IC components 306, planarization, selectively transferring or pick-and-place attaching additional IC dies or other IC components, via formation, formation of interconnect/metallization layers, attaching a structural substrate, debonding the receiver substrate (e.g., via the optional receiver release layer 312), and/or any other processing required for the finished product (e.g., an IC package).

Elements labeled with reference numerals in FIGS. 3A-I may be similar to those having similar reference numerals in FIGS. 1A-I. Further, it should be appreciated that the illustrated process flow for selective layer transfers is merely presented as an example and many other process variations are also possible, including, but not limited to, the process variations described throughout this disclosure.

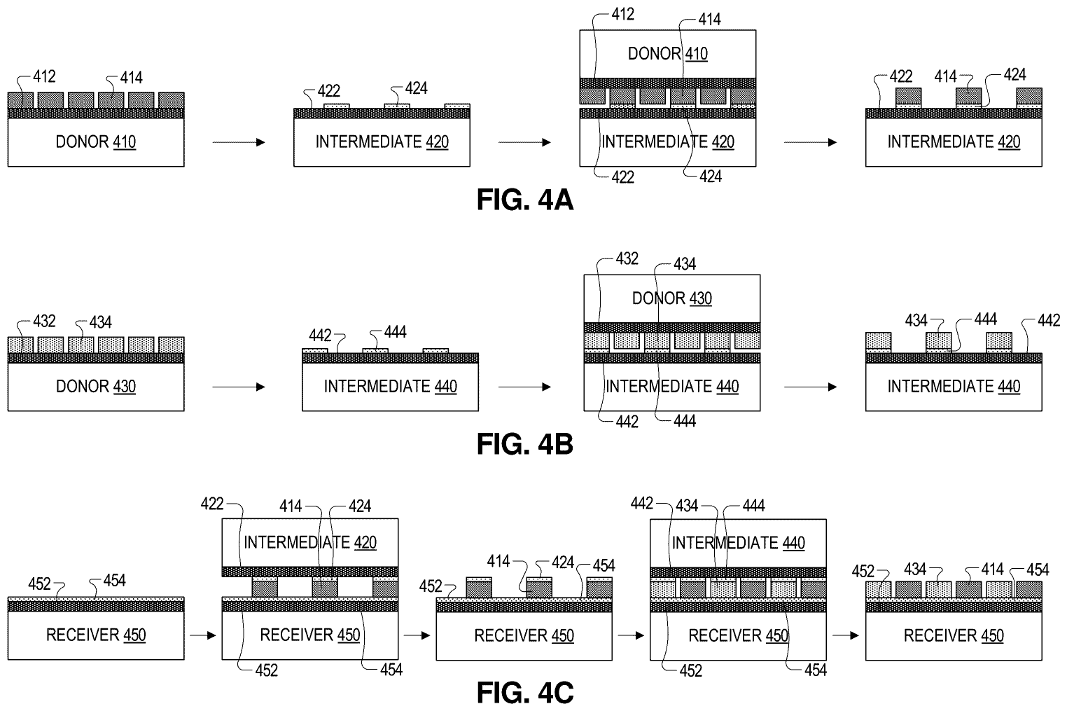

FIGS. 4A-C illustrate an example process flow for selective layer transfers from multiple donor substrates. In the illustrated example, integrated circuit (IC) components 414, 434 from multiple donor substrates 410, 430 are selectively transferred to a receiver substrate 450 using intermediate carrier substrates 420, 440. In some embodiments, the respective donors 410, 430 may have different types of IC components 414, 434, such as different types of IC dies or chiplets. In this manner, selective layer transfers can be used to transfer multiple types of IC components, such as different types of dies or chiplets, to the same receiver substrate 450. While the illustrated example depicts selective transfers from two types of donor substrates 410, 430 (e.g., with two types of types of IC components 414, 434), any number of donor substrates with any type of IC dies or other components are possible (including different die sizes).

In FIG. 4A, a layer of IC components 414 is selectively transferred from a first donor substrate 410 to an intermediate carrier substrate 420 (e.g., using any of the selective transfer flows described throughout the disclosure). For example, a release layer 412 is formed over the donor substrate 410. The layer 414 to be selectively transferred is then formed over the release layer 412 (e.g., by fabricating the layer 414 directly or blanket transferring the layer 414 from a wafer to the donor carrier 410) and diced into partially singulated IC components 414. Separately, a release layer 422 is formed over an intermediate carrier/receiver substrate 420, and a bonding template 424 is formed on the surface of the intermediate carrier 420 (e.g., above the release layer 422). The donor 410 and intermediate carrier 420 are then partially bonded together (e.g., with the target IC components 414 on the donor 410 bonded to the bonding features or adhesive areas 424 on the intermediate carrier 420). The donor 410 and intermediate carrier 420 are then debonded and separated from each other using any of the techniques described throughout this disclosure (e.g., selective release, blanket laser exposure, etc.). As a result, the target IC components 414 are debonded/separated from the donor 410 and remain on the intermediate carrier 420.

In FIG. 4B, another layer of IC components 434 is selectively transferred from a second donor substrate 430 to another intermediate carrier substrate 440 (e.g., using any of the selective transfer flows described throughout the disclosure). For example, a release layer 432 is formed over the donor substrate 430. The layer 434 to be selectively transferred is then formed over the release layer 432 (e.g., by fabricating the layer 434 directly or blanket transferring the layer 434 from a wafer to the donor carrier 430) and diced into partially singulated IC components 434. Separately, a release layer 442 is formed over an intermediate carrier/receiver substrate 440, and a bonding template 444 is formed on the surface of the intermediate carrier 440 (e.g., above the release layer 442). The donor 430 and intermediate carrier 440 are then partially bonded together (e.g., with the target IC components 434 on the donor 430 bonded to the bonding features or adhesive areas 444 on the intermediate carrier 440). The donor 430 and intermediate carrier 440 are then debonded and separated from each other using any of the techniques described throughout this disclosure (e.g., selective release, blanket laser exposure, etc.). As a result, the target IC components 434 are debonded/separated from the donor 430 and remain on the intermediate carrier 440.

In FIG. 4C, the IC components 414, 434 on both intermediate carriers 420, 440 are selectively transferred to a receiver substrate 450 (e.g., using any of the selective transfer flows described throughout the disclosure). For example, a release layer 452 is optionally formed over the receiver substrate 450 (e.g., in the event the selectively transferred IC components 414, 434 will be subsequently debonded from the receiver substrate 450 after the transfer). A bonding layer 454 (e.g., with adhesive areas or bonding features) is then formed on the surface of the receiver 450 (e.g., above the release layer 452, if included). Next, the IC components 414 on the first intermediate carrier 420 are selectively transferred to the receiver substrate 450 (e.g., using any of the selective transfer flows described throughout the disclosure). Finally, the IC components 434 on the second intermediate carrier 440 are selectively transferred to the receiver substrate 450 (e.g., using any of the selective transfer flows described throughout the disclosure).

Additional processing may then be performed on the receiver substrate 450, such as cleaning steps (e.g., removing the leftover bonding structures 424, 444 from the transferred IC components 414, 434), dielectric fill around the transferred IC components 414, 434, planarization, selectively transferring or pick-and-place attaching additional IC dies or other IC components, via formation, formation of interconnect/metallization layers, attaching a structural substrate, debonding the receiver substrate (e.g., via the optional receiver release layer 452), and/or any other processing required for the finished product (e.g., an IC package).

It should be appreciated that the illustrated process flow for selective layer transfers is merely presented as an example and many other process variations are also possible, including, but not limited to, the process variations described throughout this disclosure.

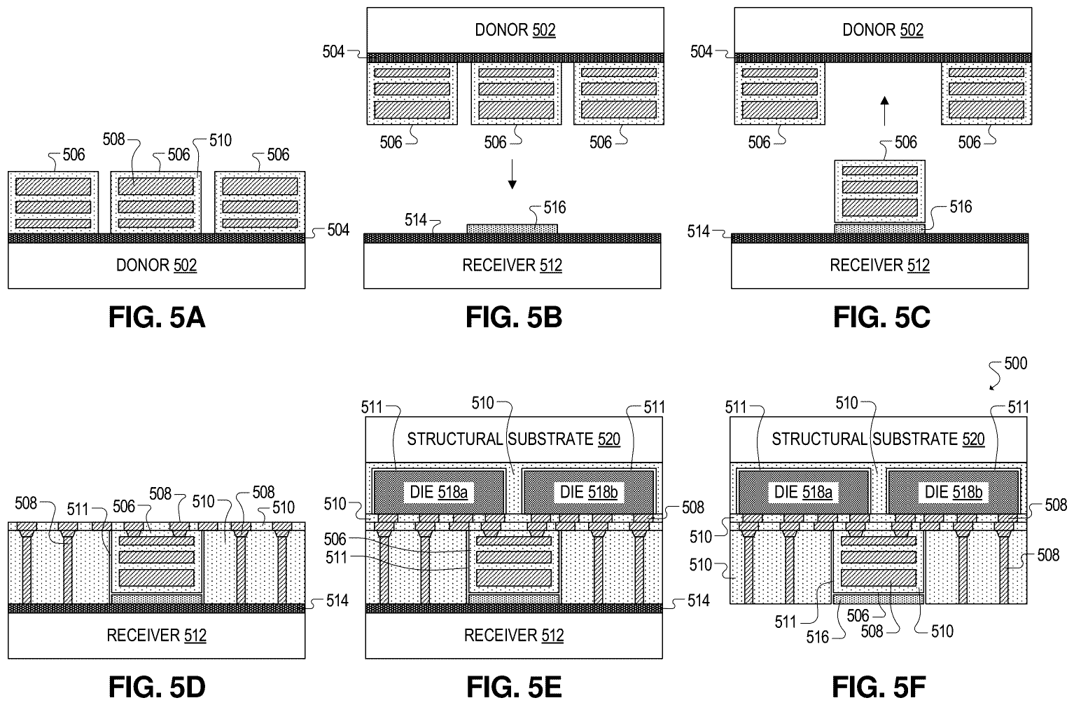

FIGS. 5A-F illustrate an example process flow for forming an integrated circuit (IC) package 500 with a selectively transferred passive interposer 506. Selective transfers can be used for a variety of applications, including transfers of active components (e.g., IC dies, transistors, diodes) and passive components (e.g., interconnects, metal-insulator-metal (MIM) chiplets, resistors, capacitors, inductors, transformers). In the illustrated example, the process flow is used to form an IC package 500 with a selectively-transferred low-cost passive interposer 506. For example, interposers 506 with high-density die-to-die (D2D) links 508 are created on a donor wafer 502 and then selectively transferred to a receiver wafer 512, which enables the same donor wafer 502 to be reused multiple times and amortizes the cost of the interconnect devices across multiple receiver wafers 512. In some embodiments, other components of the IC package 500 may also be selectively transferred, such as the IC dies 518a-b. Selective transfers can also be used for other applications, including, without limitation, transfers of photonic/optical components, and localized transfers of Group III-V semiconductors for radio frequency (RF) and high-power devices.

In FIG. 5A, repeated D2D interconnect patterns 506 are created on a release layer 504 of the donor substrate 502, and the resulting D2D interconnects are partially singulated (e.g., diced to, but not through, the donor substrate 502). The D2D interconnects 506 include high-density interconnect links 508 separated by dielectric layers 510.

In FIG. 5B, a transfer template 516 for a selective transfer is created on a release layer 514 of a receiver/carrier substrate 512. The transfer template 516 includes a dielectric bonding protrusion 516, referred to as a mesa, on the surface of the receiver substrate 512. In various embodiments, however, any suitable surface treatments or other techniques may be used to control the level of adhesion on different areas of the receiver substrate 512 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples. Further, in various embodiments, any number of buildup layers may be formed on the receiver substrate 512 prior to forming the templated connection pedestal or mesa 516 for the selective transfer.

The bonding mesa of the transfer template 516 is used to selectively transfer a D2D interconnect 506 from the donor 502 to the receiver 512 (e.g., using any of the selective transfer flows described throughout this disclosure). For example, the donor 502 and receiver 512 are aligned face to face, stacked, and then partially bonded together such that one of the D2D interconnects 506 on the donor 502 is bonded to the bonding mesa of the transfer template 516 on the receiver 512.

In FIG. 5C, the D2D interconnect 506 bonded to the receiver mesa of the transfer template 516 is debonded and/or released from the donor release layer 504 using any of the techniques described herein (e.g., selective release, blanket laser exposure, formation of bonds with strength disparities), and the donor 502 and receiver 512 are mechanically separated. As a result, the transferred D2D interconnect 506 is separated from the donor 502 and remains on the receiver 512.

In FIG. 5D, additional processing is performed to form the remaining interconnect, including dielectric (e.g., oxide) fill 510 and planarization, interconnect 508 patterning/metallization (e.g., formation of through-dielectric vias (TDVs), top metal contacts such as hybrid bonding pads, dielectric layers), and so forth.

Notably, since the D2D interposer 506 was selectively transferred while the surrounding dielectric layers 510 were fabricated directly on the receiver 512, there is a seam 511 between the transferred D2D interposer 506 and the surrounding layers 510, as shown in FIG. 5D. In general, this type of seam or transition may be present around selectively transferred components of any type since they are not formed contemporaneously with the surrounding layers.

In FIG. 5E, multiple IC dies 518a-b are attached to the top metal pads 508 (e.g., via hybrid bonding), the area around the dies 518a-b is filled with dielectric material 510 (e.g., oxide) and planarized, and a structural substrate 520 is attached (e.g., a structural silicon wafer).

The dies 518a-b may be attached using standard assembly techniques, such as pick and place, or using the selective transfer techniques described herein (e.g., similar to the transferred D2D interconnect 506).

If the dies 518a-b are attached using pick-and-place assembly, they are typically formed on a thick substrate for handling purposes and then subsequently thinned after the attach.

If the dies 518a-b are selectively transferred, however, they can be formed on—and transferred directly from—a very thin substrate. As a result, selectively transferring the dies 518a-b not only eliminates the need for post-attach thinning, it also enables the dies 518a-b to be much thinner than dies that are pick-and-place attached and subsequently thinned. Further, if the dies 518a-b are selectively transferred, there may be a seam 511 between the dies 518a-b and portions of the layers 510 surrounding the dies 518a-b, similar to the seam 511 shown around the transferred D2D interconnect 506, as described above. Moreover, because the dies 518a-b are selectively transferred, they can be different types of dies, formed on separate pieces of substrate material (e.g., separate wafers or panels) using separate processes, and then selectively transferred to the same layer of an IC device 500.

In FIG. 5F, the receiver 512 is debonded and released from the release layer 514 (e.g., using any of the techniques described herein, such as IR or UV laser ablation).

At this point, the IC package 500 may be complete, or alternatively, additional processing may be performed. For example, if the processing is performed at the wafer or panel level, the resulting IC packages 500 on the structural substrate 520 may be singulated.

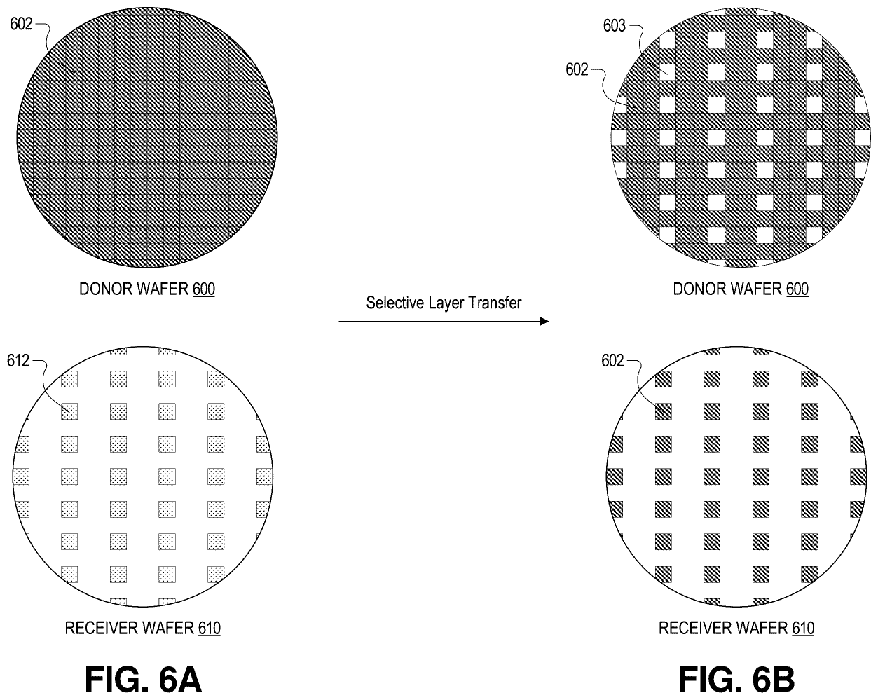

FIGS. 6A-B illustrate an example of a selective layer transfer between donor and receiver wafers 600, 610. In particular, FIG. 6A shows the wafers 600, 610 prior to the transfer, while FIG. 6B shows the wafers 600, 610 after the transfer. In the illustrated example, non-contiguous areas of the donor wafer 600 are selectively transferred to non-contiguous positions on the receiver wafer 610. In other embodiments, however, the target areas on the donor 600 and the destination areas on the receiver 610 may be partially contiguous or fully contiguous.

As shown in FIG. 6A, prior to the transfer, the donor wafer 600 includes a layer of integrated circuit (IC) components 602 (e.g., dies, chiplets, interconnects, capacitors, transistors, etc.), which may be partially singulated (e.g., diced down to, but not through, the underlying wafer 600). The receiver wafer 610 includes adhesive areas 612 patterned in non-contiguous positions on the surface (also referred to as a bonding template), which is where the target IC components 602 from the donor 600 will be transferred. In some embodiments, for example, the adhesive areas 612 may be raised structures or protrusions (referred to as “mesas”) patterned on the surface of the receiver 612. Moreover, in some embodiments, the adhesive areas 612 on the receiver 610 may have a similar footprint as the target IC components 602 on the donor 600. In various embodiments, however, any suitable surface treatments or other techniques may be used to control the level of adhesion on different areas of the receiver substrate 610 (e.g., to form adhesive and non-adhesive areas for selective transfers), including, without limitation, surface topography variations (e.g., mesas, recesses), use of materials with high and/or low adhesion, treatments using hydrophobic materials and/or self-assembled monolayers (SAMs), and/or surface activation techniques, among other examples.

As shown in FIG. 6B, after the transfer, the target IC components 602 have been transferred from the donor wafer 600 to the receiver wafer 610. As a result, the donor wafer 600 includes empty areas 603 where the transferred IC components 602 were located, while the receiver wafer 610 includes the transferred IC components 602 in the positions where the adhesive areas 612 were patterned. In particular, individual IC components 602 from the donor wafer 600 are now bonded to individual adhesive areas 612 on the receiver wafer 610.

While the illustrated example depicts a selective transfer between two wafers, selective transfers can be performed between panels or other substrates of any shape or size, including substrates with mismatched shapes and sizes.

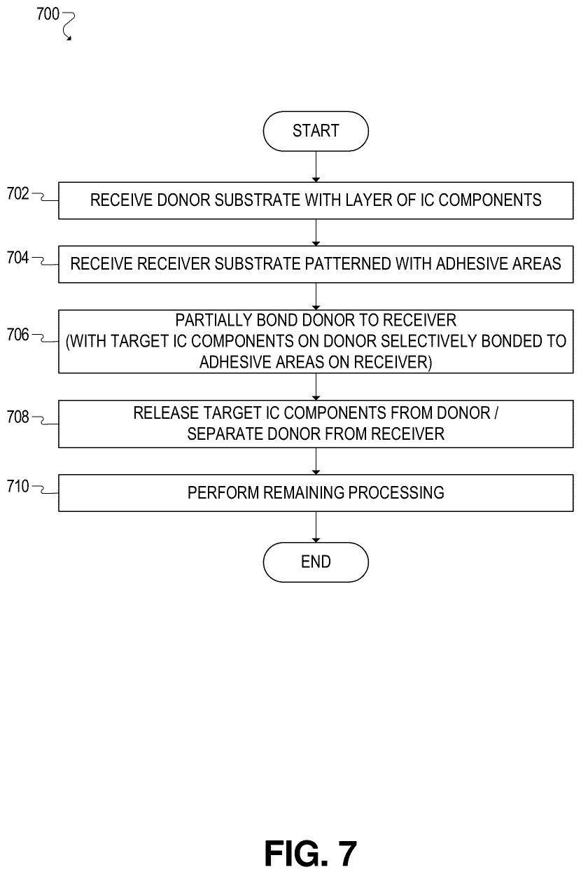

FIG. 7 illustrates a flowchart 700 for performing selective layer transfers. It will be appreciated in light of the present disclosure that the illustrated process flow is only one example methodology for performing selective layer transfers. Moreover, the steps of the illustrated process flow may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metal-organic chemical vapor deposition (MOCVD), molecular beam epitaxy (MBE), atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

The flowchart begins at block 702 by receiving a first substrate with a layer of integrated circuit (IC) components, which may be referred to as the donor substrate. In some embodiments, the donor substrate may include a base substrate, a release layer over the base substrate, and a (partially singulated) layer of IC components over the release layer.

In some embodiments, the donor substrate may be formed by receiving the base substrate, forming the release layer over the base substrate, forming the layer of IC components over the release layer (e.g., by fabricating or transferring the layer of IC components over the release layer), and partially singulating the layer of IC components (e.g., by dicing through the layer of IC components without dicing through the base substrate).

In various embodiments, the layer of IC components may include one or more IC dies, interconnects, transistors, diodes, resistors, capacitors, inductors, transformers, optical components, and/or any other active or passive circuitry or components.

The base substrate may be made of one or more materials that include elements such as silicon (Si), oxygen (O), carbon (C), hydrogen (H), and/or Group III-V elements (e.g., aluminum (Al), gallium (Ga), indium (In), nitrogen (N), phosphorus (P), arsenic (As), antimony (Sb)), including, without limitation, silicon (Si), silicon dioxide (silica or SiO₂), silicon on insulator (SOI), quartz, glass, Group III-V materials (e.g., gallium nitride (GaN), aluminum gallium nitride (GaN), gallium arsenide (GaAs), indium gallium arsenide (InGaAs), indium phosphide (InP)), and epoxies/resins (e.g., IR or UV transparent epoxies).

The release layer may include one or more layers of varying materials depending on the type of release or debonding technology used. For example, for IR laser debonding, the release layer may include one or more layers of material(s) capable of absorbing and/or reflecting infrared (IR) electromagnetic radiation, such as a thin metal layer or multiple metal layers (e.g., aluminum (Al), tungsten (W), copper (Cu), titanium (Ti), titanium nitride (TiN), tantalum (Ta), tantalum nitride (TaN)). For UV laser debonding, the release layer may include one or more layers of material(s) capable of absorbing ultraviolet (UV) electromagnetic radiation (e.g., organic polymers such as polyimides). In some embodiments, the release layer may additionally or alternatively include one or more layers of dielectric materials to buffer laser ablation and thermal energy, control thin film interference or adhesion, and/or provide residual adhesion after other materials and/or layers in the release layers are weakened, removed, and/or ablated by a laser (e.g., silicon dioxide (SiO₂), silicon nitride (Si₃N₄), silicon oxynitride (SiON), silicon carbide (SiC), silicon carbon nitride (SiCN), silicon oxycarbon nitride (SiOCN), aluminum oxide (Al₂O₃), low-k dielectrics such as carbon-doped oxide (CDO) or porous silicon dioxide (SiO₂), titanium dioxide (TiO₂), tantalum oxide (Ta₂O₅)). Thus, in some embodiments, the release layer(s) may be made of one or more materials that include elements such as aluminum (Al), tungsten (W), copper (Cu), titanium (Ti), tantalum (Ta), silicon (Si), oxygen (O), nitrogen (N), hydrogen (H), and carbon (C), including, without limitation, any of the materials referenced above.

The flowchart then proceeds to block 704 to receive a second substrate with one or more adhesive areas, which may be referred to as the receiver substrate. In some embodiments, the receiver substrate may include a base substrate patterned with one or more adhesive areas on the surface, such as a layer of raised bonding structures or “mesas” over the base substrate. The receiver substrate may also optionally include a release layer over the base substrate (e.g., to enable the base substrate to be subsequently debonded after the transfer) and/or one or more additional buildup layers and/or IC components.

In some embodiments, the receiver substrate may be formed by receiving the base substrate, optionally forming a release layer over the base substrate, optionally forming additional buildup layers and/or IC components over the base substrate (e.g., over the optional release layer, if included), and forming the adhesive areas (e.g., bonding structures) on the surface of the receiver substrate (e.g., over the previously referenced layers, if included). In some embodiments, the base substrate and the optional release layer of the receiver may be made of any of the materials referenced above for the base substrate and the release layer of the donor, respectively.

In some embodiments, the adhesive areas may include mesa structures with similar footprints as the corresponding IC components to be transferred from the donor (although, in some cases, the mesas may be slightly larger or smaller than the IC components to accommodate alignment and manufacturing tolerances). The mesa structures may be made of varying materials depending on the type of bond and/or whether electrical connections are needed through the bond interface for the subsequently bonded IC components (e.g., dielectric material, metal, or both). For example, the mesa structures may include blanket dielectric structures with no conductive contacts (e.g., for dielectric-to-dielectric bonds), dielectric structures with conductive contacts (e.g., for hybrid dielectric and metal bonds), and/or conductive contacts by themselves (e.g., for metal-to-metal bonds). Thus, in some embodiments, the mesa structures may be made of one or more materials that include elements such as silicon (Si), oxygen (O), hydrogen (H), nitrogen (N), carbon (C), aluminum (Al), tungsten (W), copper (Cu), titanium (Ti), tantalum (Ta), including, without limitation, inorganic dielectrics such as silicon dioxide (SiO₂), silicon nitride (Si₃N₄), and/or silicon carbon nitride (SiCN), organic dielectrics such as photoresists and adhesives, and/or conductive materials such as metals and alloys (e.g., any of the foregoing metal elements and/or compounds/alloys thereof).

In various embodiments, however, any suitable technique(s) may be used to control the level of adhesion on different areas of the receiver substrate. For example, a variety of surface treatments (e.g., lithographically or additively manufactured) can be used to enhance and/or reduce adhesion in select areas of the receiver substrate, including, without limitation, modifying the surface topography (e.g., raised vs. recessed areas, smooth vs. rough areas), use of materials with high and/or low adhesion (e.g., forming layers with adhesive and non-adhesive materials in select areas), treatments using hydrophobic materials and/or self-assembled monolayers (SAMs), and/or surface activation techniques (e.g., plasma or wet activation), among other examples.

For example, the surface topography of the receiver substrate may be modified (e.g., using techniques such as deposition, lithography, etching, roughening) to form areas with different levels of adhesion, such as raised (e.g., adhesive) and recessed (e.g., non-adhesive) areas, smooth (e.g., adhesive) and rough (e.g., non-adhesive) areas, etc.

As another example, the surface of the receiver substrate may be patterned with materials having high and/or low adhesion in select areas. For example, a layer patterned with different areas of adhesive and non-adhesive materials may be formed on the receiver substrate. In some embodiments, the adhesive material may include silicon dioxide (SiO₂) or silicon carbon nitride (SiCN) to promote strong oxide fusion bonds, silicon carbide (SiC) to provide lower thermal contact resistance compared to SiO₂ or SiCN, and/or metal to form electrical connections. Further, in some embodiments, the non-adhesive material may include silicon nitride (Si₃N₄) to form weak or no bonds.

As another example, treatments using hydrophobic materials and/or self-assembled monolayers (SAMs) may be used to enhance and/or reduce adhesion in select areas of the receiver substrate (e.g., using a SAM treatment to create monolayers with high and/or low adhesion in select areas). In some embodiments, the hydrophobic material may include a SAM material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may also be used. In some embodiments, the hydrophobic material may include a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used in other embodiments.

As another example, surface activation techniques may be used to enhance and/or reduce adhesion in select areas of the receiver substrate, including, without limitation, plasma or wet activation.

The flowchart then proceeds to block 706 to partially bond the donor substrate to the receiver substrate (e.g., face to face), such that one or more target IC components on the donor substrate are selectively bonded to the one or more adhesive areas on the receiver substrate. The donor and receiver substrates may be partially bonded using any suitable bonding techniques, including, without limitation, hybrid bonding, fusion bonding, and/or adhesive bonding.

The flowchart then proceeds to block 708 to release the target IC components from the donor substrate and separate the donor substrate from the receiver substrate. In this manner, when the donor and receiver substrates are separated, the target IC components are separated from the donor substrate and remain on the receiver substrate.

In some embodiments, the donor and receiver substrates may be debonded/separated from each other by releasing, at least partially, the target IC components from the release layer of the donor substrate and then mechanically separating the donor and receiver substrates. For example, in some embodiments, the target IC components may be fully released from the donor substrate by selectively debonding them from the donor release layer using a laser (e.g., an IR or UV laser), or alternatively, the target IC components may be partially released from the donor substrate by weakening the donor release layer using a laser (e.g., an IR or UV laser). After fully or partially releasing the target IC components from the donor, the donor and receiver substrates are mechanically separated, and post separation, the target IC components remain bonded to the receiver and are no longer on the donor.

Alternatively, or additionally, the donor release layer and the receiver bonding structures may be formed with respective materials that have disparate bond strengths-such that the target IC components have a stronger bond to the receiver than the donor-thus causing the target IC components to debond from the donor and remain on the receiver when the donor and receiver are mechanically separated.

The flowchart then proceeds to block 710 to perform any remaining processing, such as dielectric filling and planarization, attaching additional IC dies or components (e.g., via selective transfers or pick-and-place assembly), forming interconnects (e.g., vias, traces), attaching a structural substrate, debonding the receiver base substrate (e.g., via the optional receiver release layer), and/or any other processing required for the finished product (e.g., an IC package, device, system, etc.).

The completed product may include a variety of components and circuitry (some of which may have been selectively transferred), including electrical components (e.g., electronic integrated circuits (EICs), processors, XPUs, controllers, memory), optical components (e.g., optical interfaces, photonic integrated circuits (PICs), optical connectors, fibers), and/or radio frequency (RF) or high-voltage components (e.g., high-voltage electrostatic discharge (ESD) devices, power amplifiers (PAs), low noise amplifiers (LNAs), voltage controlled oscillators (VCOs), surface acoustic wave (SAW)/bulk acoustic wave (BAW) devices or filters, bandpass filters (BPFs), intermediate-frequency (IF) amplifiers, frequency synthesizers, mixers, RF digital-to-analog converters (DACs), RF analog-to-digital converters (ADCs), thick gate oxide devices, Group III-V devices/chiplets, passive RF devices such as interconnects, antennas, and inductors).

Further, in some embodiments, the resulting IC package or product may be electrically coupled to a circuit board and/or incorporated into an electronic device or system (e.g., with other electronic components).

At this point, the flowchart may be complete. In some embodiments, however, the flowchart may restart and/or certain blocks may be repeated. For example, in some embodiments, the flowchart may restart at block 702 to continue performing selective transfers.

### Architectures for Facilitating Bonding in Wafer-Level Selective Transfers

In a typical wafer-to-wafer bonding process (where an entire wafer is bonded to another wafer), a generally flat surface of a first wafer may be placed in contact with a generally flat surface of a second wafer. The bonding process may begin with the centers of the wafers being pressed together (e.g., using mechanical pressure). This may result in the centers of the wafers being bonded together. This bonding may cause areas surrounding the center of the wafers to be brought closer together. The close proximity of these surrounding areas facilitates the bonding process for these surrounding areas. As these areas bond, they cause other surrounding areas to be brought closer together. This process may repeat until the perimeters of the wafers are reached and the wafers are bonded together. This process may be referred to as bond wave propagation as the bonding propagates from a particular location (e.g., the center of the wafers) to other locations (e.g., outwards towards the perimeter of the wafers).

Various solutions described herein introduce wafer-level selective transfer, wherein only selected features (e.g., IC components 106) of a wafer (rather than the entire wafer) are transferred to another wafer. However, wafer-level selective transfer does present challenges to bond wave propagation. For example, the donor wafer and/or the receiver wafer may have topography on their surfaces. For example, the features of a donor wafer that are to be transferred to a receiver wafer may be dispersed throughout the wafer with spaces in between the features that have a different height than the features. Singulation performed on the donor wafer may also result in topography on the donor wafer. As another example, a receiver wafer may include bonding features that are elevated relative to areas around the bonding features. The topography may impede bond wave propagation as it may increase the spacing between wafer locations that are bonding together and the surrounding locations that need to be bonded.

Various embodiments of the present disclosure provide bonding features to facilitate the bonding of wafers with topography to enable wafer-level selective transfer. In addition to the target features (e.g., IC components) to be transferred, a wafer may also include bonding features that facilitate bond wave propagation. These additional bonding features will be transferred to the receiver wafer as well, but (at least in some embodiments) are not electrically connected to any other component and/or don't serve any function after the bonding process is complete. The additional features provide an increased area for bonding and help with providing a continuous bonding surface, improving bond wave propagation across the wafer.

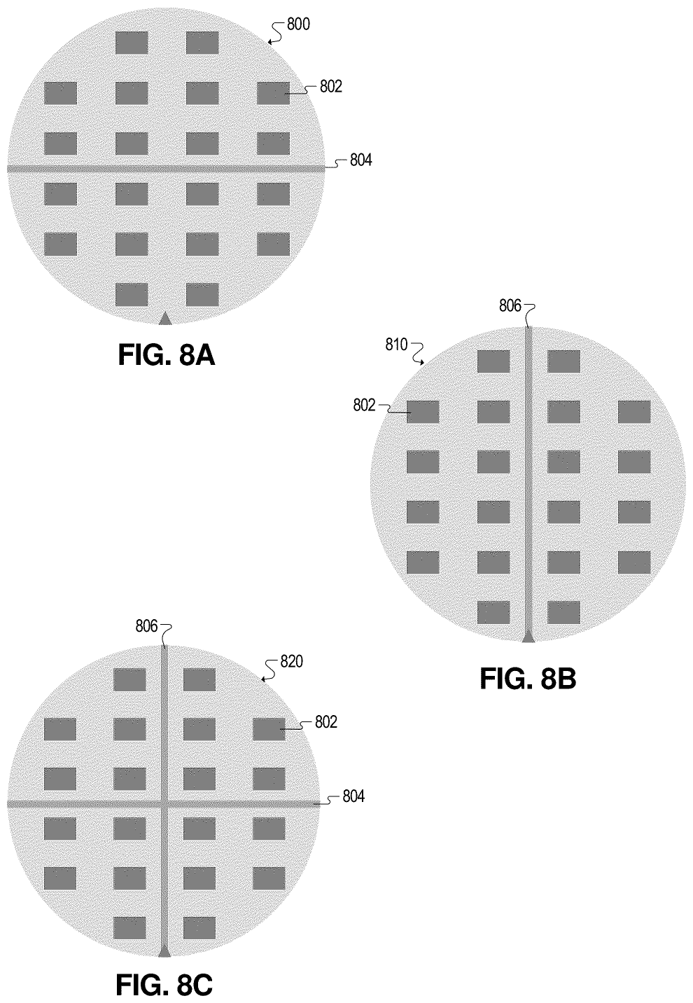

FIGS. 8A-C illustrate donor substrates (e.g., wafers) with bonding features patterned as strips to facilitate bonding in wafer-level selective transfers. These strips facilitate bond wave propagation by providing a continuous bonding surface extending out from the center of the donor wafer. In these particular embodiments, the bonding features are formed on the wafer, but are not contiguous with (e.g., they do not contact) the target features 802 to be selectively transferred to a receiver wafer (in additional embodiments described below the bonding features may be contiguous with the target features).

FIG. 8A depicts a bonding feature 804 that is implemented as a continuous strip in the X direction (e.g., East-West) across the top of the donor wafer 800. During wafer-to-wafer bonding, the bonding feature 804 provides a continuous surface for bond wave propagation despite the discontinuities between the different target features 802 (e.g., dies) that are being transferred to a receiver substrate (e.g., wafer). In various embodiments, the strip may be between 10 micrometers and 1 millimeter wide. The strip may be approximately the same height as the other features 802 that are being transferred to the receiver wafer.

During wafer-level selective transfer, the strip on the donor wafer 800 mates with the surface of the receiver wafer. In various embodiments, the surface of the receiver wafer may be substantially flat or may have a bonding feature which substantially matches the shape of the feature 804 on the donor wafer. When the receiver wafer comprises such a bonding feature, it may be substantially the same height as other bonding features of the receiver wafer (e.g., bonding features that have substantially the same footprint as the features 802 to be transferred).

The target features 802 (and similar features in the following FIGS.) may correspond to the IC components described herein (e.g., 106, 206, 306, 414, etc.). A bonding feature (e.g., feature 804 or the bonding features described below) may be formed in the same layer (e.g., a selective transfer layer) as the features 802.

In some embodiments, the bonding feature 804 may undergo the same surface treatment(s) that are applied to the features 802. For example, such surface treatments may include e.g., one or more of metallization (e.g., application of a thin metal layer to be used to bond the features to the receiver wafer), surface cleaning (e.g., removing particles or residues using pressurized water or solvent), plasma activation (e.g., a treatment such as a nitrogen gas that activates a surface to increase the likelihood that the surface will bond to another surface), wet activation, etc.

One or more layers underneath a bonding feature (e.g., 804) may also be similar to one or more layers underneath features 802. For example, the bonding feature 804 may be formed over a base substrate and a release layer. When the features 802 are transferred to the receiver substrate, the bonding feature 804 may be separated from the underlying release layer and bonded to the receiver substrate as well.

In some embodiments, after at least a portion of features 802 and the bonding feature(s) (e.g., 804) have been transferred to a receiver substrate, the release layer for the features 802 and the bonding feature(s) (e.g., 804) may be repatterned in preparation for selectively transferring additional features 802 from the donor substrate (e.g., wafer 800) to a different receiver substrate. For example, if only some of the features 802 of wafer 800 were transferred to a first receiver wafer, then the bonding feature 804 may be repatterned and used during transfer of others of the features 802 to a second receiver wafer. As another example, if all of the features 802 were transferred to a first receiver wafer with the bonding feature 804, the features 802 and the bonding feature 804 may be repatterned on wafer 800 and transferred to a second receiver wafer, and so on.

FIG. 8B depicts a bonding feature 806 that is implemented as a continuous strip in the Y direction (e.g., North-South) across the donor wafer 810. The donor wafer 810 and the bonding feature 806 may have any suitable characteristics of the donor wafer 800 and bonding feature 804 respectively. FIG. 8B illustrates that various orientations may be used for the bonding feature 806 that facilitates the bond wave propagation.

In other embodiments, a donor wafer may comprise a feature implemented as a strip across the wafer at any other suitable orientation. For example, the strip may be angled (e.g., be oriented in both the x and y directions), such as at a 45 degree angle relative to the X (and Y) direction. In various embodiments, the strip may extend from one point on the perimeter of the donor wafer to another point on the perimeter. In other embodiments, the strip may extend through a majority of the diameter of a wafer, but does not extend all the way to one or both edges. In various embodiments, the strip may pass through or near the center point of the wafer.

In some embodiments, multiple bonding features (e.g., strips) may be formed on the donor wafer to facilitate bond wave propagation during selective transfer. For example, FIG. 8C depicts a first bonding feature 804 and a second bonding feature 806 that is orthogonal to the first bonding feature. In this embodiment, both bonding features pass through the center point of the donor wafer 820 and extend across the wafer from edge to edge.

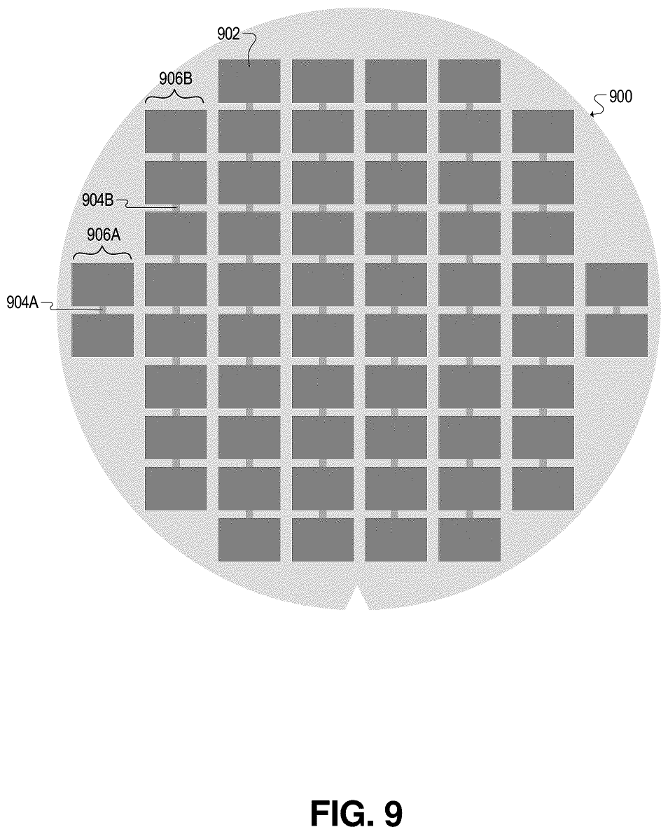

FIG. 9 illustrates a wafer 900 with bonding features in the form of tethers 904 between target features 902 (e.g., dies) to facilitate bonding in wafer-level selective transfers. In some embodiments, rather than having one or more bonding features that are non-contiguous with the features to be transferred (as illustrated in FIGS. 8A-C), the bonding features may be attached to the features 902 to be selectively transferred. In FIG. 9, these bonding features are shown as tethers 904 between adjacent features 902. During bonding, these tethers may facilitate a continuous bond wave propagation from the center of the wafer to one or more edges of the wafer.

In some embodiments, the features 902 that are tethered together are transferred together to the same receiver wafer. For example, the features 902 in a first column 906A that are connected by tether 904A may be transferred to a first receiver wafer, while the features 902 in a second column 906B that are connected together by other tethers (including tether 904B) may be transferred to a second receiver wafer, and so on. In various embodiments, any selection of one or more of the columns of features 902 depicted may be transferred to the same receiver wafer, while another selection of one or more other columns of features 902 may be transferred to a different receiver wafer, and so on.

The tethers 904 (and the tethers described below) may have any suitable characteristics described above with respect to the bonding features 804 and 806. Although the tethers are all shown in the Y direction, they could alternatively all be oriented in the X direction, or in other suitable directions, e.g., as discussed below.

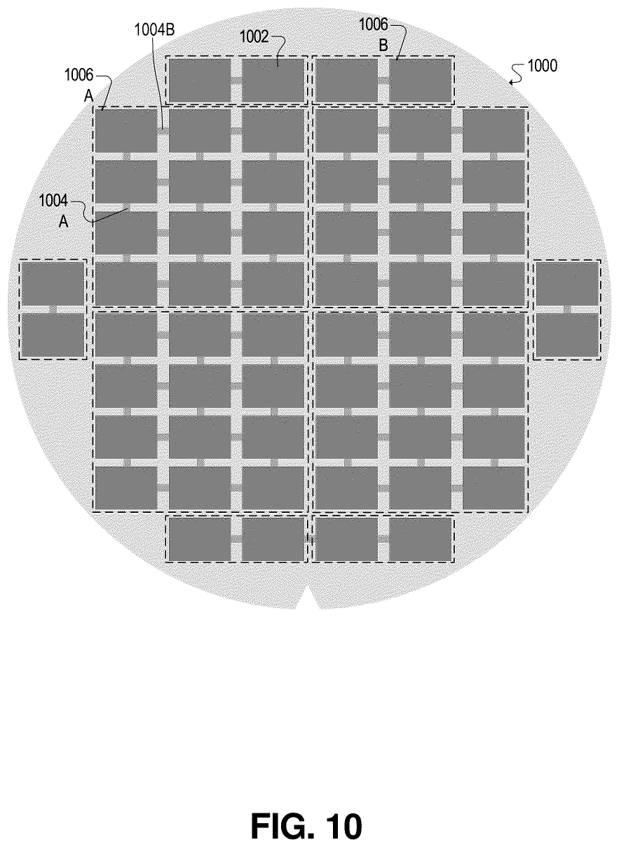

FIG. 10 illustrates a wafer 1000 with tethers 1004 in orthogonal directions between features 1002 (e.g., dies) to facilitate bonding in wafer-level selective transfers. As depicted, some of these tethers (e.g., 1004A) are oriented in the Y direction, and some (e.g., 1004B) are oriented in the X direction.

In some embodiments, the features 1002 that are tethered together (shown as various groups bounded by dotted lines) are transferred together to the same receiver wafer. For example, the twelve features 1002 in a first group 1006A may be transferred together while the two features 1002 in a second group 1006B may be transferred together (to the same receiver wafer as the first group or to a different receiver wafer). In various embodiments, any selection of one or more of the groups of features 1002 depicted may be transferred to the same receiver wafer, while another selection of one or more other groups of features 1002 may be transferred to a different receiver wafer, and so on. In various embodiments, the tethers may be used to group the features 1002 in any suitable arrangements.

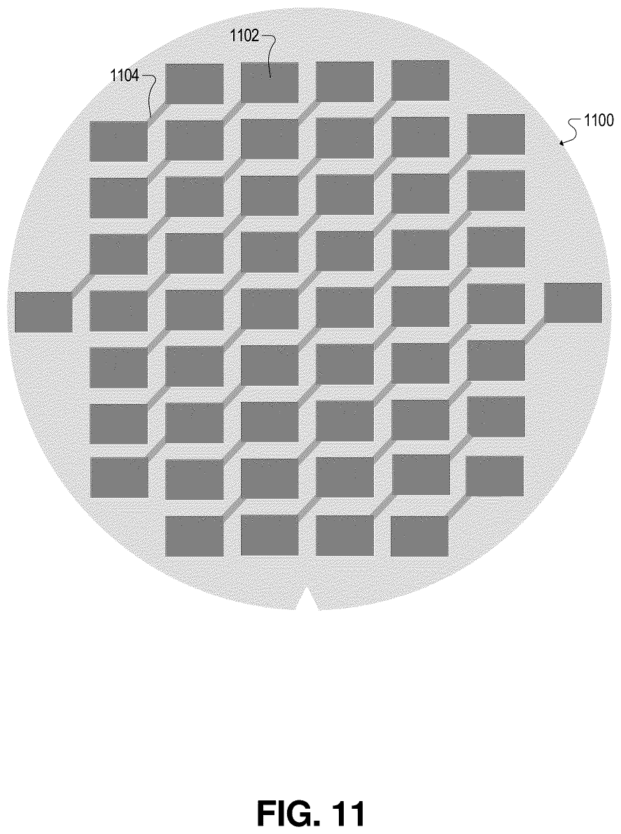

FIG. 11 illustrates a wafer 1100 with diagonally oriented tethers 1104 between features 1102 (e.g., dies) to be selectively transferred. The tethers 1104 may facilitate bonding in wafer-level selective transfers. In the depicted embodiment, a tether 1104 extends from a corner of one feature to a corner of another feature in a diagonal (e.g., angled) orientation. In other embodiments, a tether 1104 could be attached to a portion of a feature 1102 that is not a corner. For example, a tether 1104 could be diagonally oriented and attached to a side of one feature 1102 and to a side of another features 1102. As another example, a tether could be attached to a corner of one feature and to a side of another feature. As in previous embodiments, the groups of features 1102 that are tethered together may be selectively transferred together to the same receiver wafer.

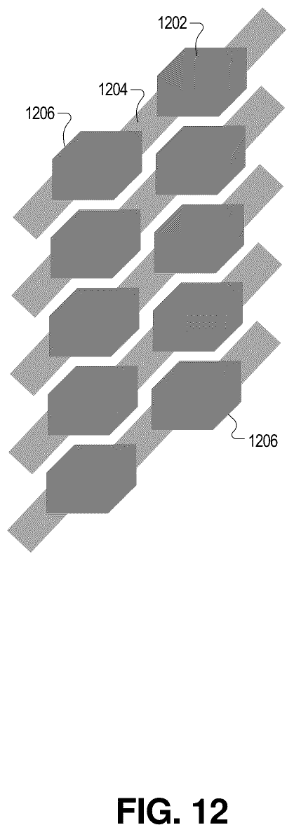

FIG. 12 illustrates tethers 1204 between features 1202 (e.g., dies) with chamfered corners 1206 to facilitate bonding in wafer-level selective transfers. The tethers 1204 and features 1202 could be present, for example, on a donor wafer in a manner similar to that described above for the other features and tethers (or other bonding features). In this embodiment, a feature 1202 has a generally rectilinear shape, but with opposite corners 1206 being chamfered (thus the die would be rectilinear but for the chamfered corners). This enables the width of tethers 1204 that are diagonally oriented to be increased, thus increasing the surface area available for bonding. For example, a tether 1204 may occupy a portion of the space that would otherwise be occupied by an adjacent feature 1202 if the feature were to have the same rectilinear shape without the chamfered corners. In other words, features 1202 with chamfered corners may be designed to allow for the use of wider tethers 1204 which would otherwise intersect with the corners of the features if they were not chamfered.

The increased width of the tethers 1204 in this embodiment may provide improved bond wave propagation relative to more narrow tethers. As in previous embodiments, the groups of features 1102 that are tethered together may be selectively transferred together to the same receiver wafer.

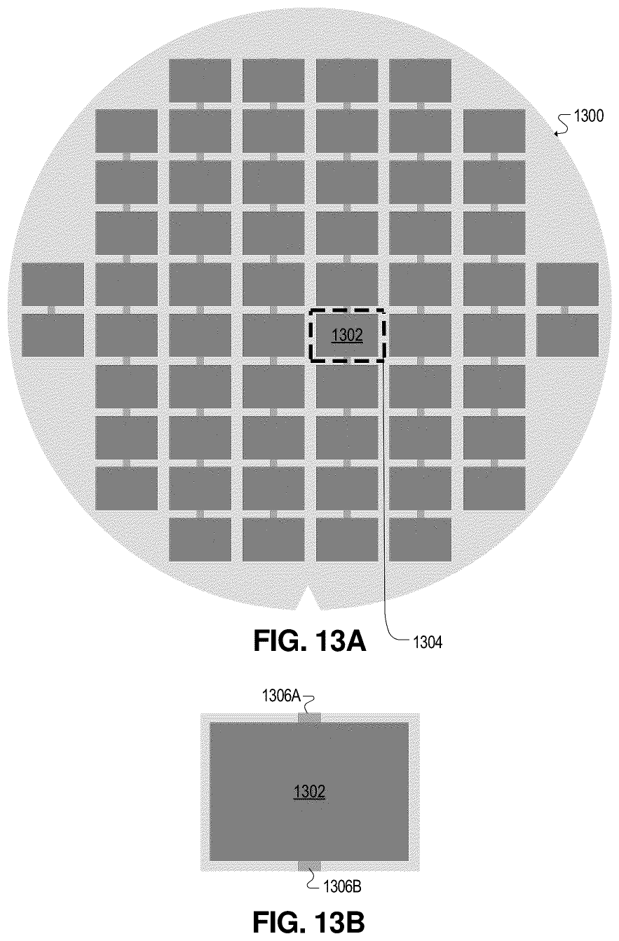

FIGS. 13A-B illustrate a wafer 1300 with tethered features 1302 (e.g., dies) and a singulated feature 1302 with tether stubs 1306. The wafer 1300 is similar to wafer 900. The dotted lines around the feature 1302 are representative of singulation that may be performed on the receiver wafer after the tethered features 1302 are transferred. As the singulation cut (or etch or other means of singulation) will generally not perfectly match the footprint of a transferred feature 1302, a small portion of a tether, referred to herein as a tether stub 1306 may remain attached to the feature 1302 after the singulation (and may also be present when the feature 1302 is placed in an integrated circuit package and/or other electronic device). For features 1302 that are tethered to multiple other features on the donor wafer, a tether stub 1306 may be present for each other feature that the feature 1302 is tethered to. Thus, multiple tether stubs 1306 may extend from the feature 1302 in opposing directions. In the embodiment depicted, a first tether stub 1306A extends in one direction while a second tether stub 1306B extends in the opposite direction. In various embodiments, the tether stubs 1306 are physically connected, but not electrically connected to the feature 1302. A tether stub 1306 may also rest on a portion of a bonding structure (e.g., a mesa) that also is under the feature 1302. The footprint of the bonding structure may be similar to the combined footprint of the feature 1302 and the one or more tether stubs 1306 connected to the feature 1302 (in some embodiments, the bonding structure may be singulated along with the tether(s)).

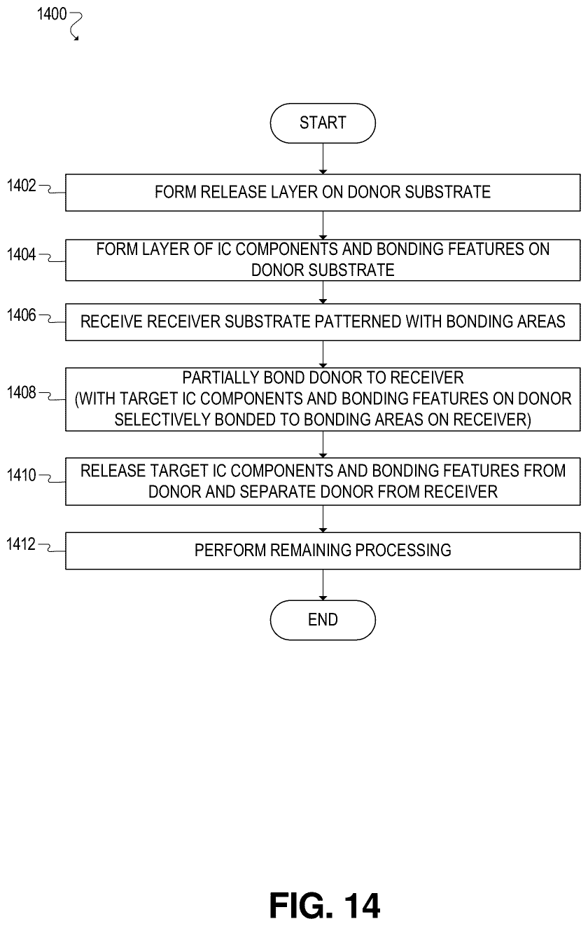

FIG. 14 illustrates a flowchart 1400 for performing selective layer transfers using bonding features of a donor substrate. It will be appreciated in light of the present disclosure that the illustrated process flow is only one example methodology for performing selective layer transfers. Moreover, the steps of the illustrated process flow may be performed using any suitable semiconductor fabrication techniques.

The flowchart begins at block 1402 by forming a release layer on a donor substrate. In some embodiments, the release layer may be formed over a base substrate of the donor substrate.

At 1404, a layer of IC components and bonding features are formed on the donor substrate. For example, the layer of IC components and bonding features may be formed over the release layer (e.g., by fabricating the layer of IC components and bonding features over the release layer or by transferring the layer, e.g., from a carrier wafer). In some embodiments, the layer of IC components and bonding features may also be partially singulated (e.g., by dicing through the layer of IC components without dicing through the base substrate and/or the bonding features).

In various embodiments, the base substrate and release layer may have any suitable characteristics of other base substrates and release layers described herein, such as in connection with FIG. 7. The layer of IC components and bonding features may have any suitable characteristics of the layers of IC components described herein.

In various embodiments, the bonding features (such as strips and tethers) may comprise any materials that are the same as or similar to materials of the features that are being transferred or the mesa structures. For example, the bonding features may comprise any one or more of materials that include elements such as silicon (Si), oxygen (O), carbon (C), hydrogen (H), and/or Group III-V elements (e.g., aluminum (Al), gallium (Ga), indium (In), nitrogen (N), phosphorus (P), arsenic (As), antimony (Sb)), including, without limitation, silicon (Si), silicon dioxide (silica or SiO₂), silicon on insulator (SOI), quartz, glass, Group III-V materials (e.g., gallium nitride (GaN), aluminum gallium nitride (GaN), gallium arsenide (GaAs), indium gallium arsenide (InGaAs), indium phosphide (InP)), epoxies/resins (e.g., IR or UV transparent epoxies), inorganic materials such as silicon, silicon on insulator (SOI), quartz, glass, inorganic dielectrics such as silicon dioxide (SiO₂), silicon nitride (Si₃N₄), silicon oxy nitride (SiON), and/or silicon carbon nitride (SiCN), organic dielectrics such as photoresists and adhesives, conductive materials such as metals, and combinations thereof.

The flowchart then proceeds to block 1406 to receive a second substrate with one or more bonding areas, which may be referred to as the receiver substrate. In some embodiments, the receiver substrate may include a base substrate patterned with one or more bonding areas on the surface, such as a layer of raised bonding structures or “mesas” over the base substrate. The receiver substrate may also optionally include a release layer over the base substrate (e.g., to enable the base substrate to be subsequently debonded after the transfer) and/or one or more additional buildup layers and/or IC components.

In some embodiments, the receiver substrate may be formed by receiving the base substrate, optionally forming a release layer over the base substrate, optionally forming additional buildup layers and/or IC components over the base substrate (e.g., over the optional release layer, if included), and forming the bonding areas (e.g., bonding structures) on the surface of the receiver substrate (e.g., over the previously referenced layers, if included). In some embodiments, the base substrate and the optional release layer of the receiver may be made of any of the materials referenced above for the base substrate and the release layer of the donor, respectively.

In some embodiments, the bonding areas may include mesa structures with similar footprints as the corresponding IC components and/or bonding features to be transferred from the donor (although, in some cases, the mesas may be slightly larger or smaller than the IC components and/or bonding features of the donor to accommodate alignment and manufacturing tolerances). The bonding areas (e.g., mesa structures) may include any suitable characteristics of other bonding areas (e.g., mesa structures) described herein, e.g., in connection with FIG. 7.

The flowchart then proceeds to block 1408 to partially bond the donor substrate to the receiver substrate (e.g., face to face), such that one or more target IC components and bonding features on the donor substrate are selectively bonded to the one or more bonding areas on the receiver substrate. The donor and receiver substrates may be partially bonded using any suitable bonding techniques, including, without limitation, hybrid bonding, fusion bonding, and/or adhesive bonding.

In some embodiments, the receiver substrate may be held in place (e.g., with a vacuum chuck) and the donor substrate is suspended over the receiver substrate. Downward pressure (e.g., via a mechanical mechanism such as a pin) may be applied to the center of the donor substrate to press the center of the donor substrate together with the center of the receiver substrate. This may result in the centers bonding and may initiate bond wave propagation from the center to the perimeter of the substrates.

The flowchart then proceeds to block 1410 to release the target IC components and bonding features from the donor substrate and separate the donor substrate from the receiver substrate. In this manner, when the donor and receiver substrates are separated, the target IC components and bonding features are separated from the donor substrate and remain on the receiver substrate. This may be accomplished in any suitable manner, such as using the techniques described above (e.g., in connection with FIG. 7).

The flowchart then proceeds to block 1412 to perform any remaining processing, such as dielectric filling and planarization, singulation, attaching additional IC dies or components (e.g., via selective transfers or pick-and-place assembly), forming interconnects (e.g., vias, traces), attaching a structural substrate, debonding the receiver base substrate (e.g., via the optional receiver release layer), and/or any other processing required for the finished product (e.g., an IC package, device, system, etc.).

The completed product may include a variety of components and circuitry (some of which may have been selectively transferred), including electrical components (e.g., electronic integrated circuits (EICs), processors, XPUs, controllers, memory), optical components (e.g., optical interfaces, photonic integrated circuits (PICs), optical connectors, fibers), and/or radio frequency (RF) or high-voltage components (e.g., high-voltage electrostatic discharge (ESD) devices, power amplifiers (PAs), low noise amplifiers (LNAs), voltage controlled oscillators (VCOs), surface acoustic wave (SAW)/bulk acoustic wave (BAW) devices or filters, bandpass filters (BPFs), intermediate-frequency (IF) amplifiers, frequency synthesizers, mixers, RF digital-to-analog converters (DACs), RF analog-to-digital converters (ADCs), thick gate oxide devices, Group III-V devices/chiplets, passive RF devices such as interconnects, antennas, and inductors).

Further, in some embodiments, the resulting IC package or product may be electrically coupled to a circuit board and/or incorporated into an electronic device or system (e.g., with other electronic components).

At this point, the flowchart may be complete. In some embodiments, however, the flowchart may restart and/or certain blocks may be repeated. It will be appreciated in light of the present disclosure that the illustrated process flow is only one example methodology for performing selective layer transfers of thermal management dies. Moreover, the steps of the illustrated process flow may be performed using any suitable semiconductor fabrication techniques such as those described herein or other suitable techniques.

### EXAMPLE EMBODIMENTS

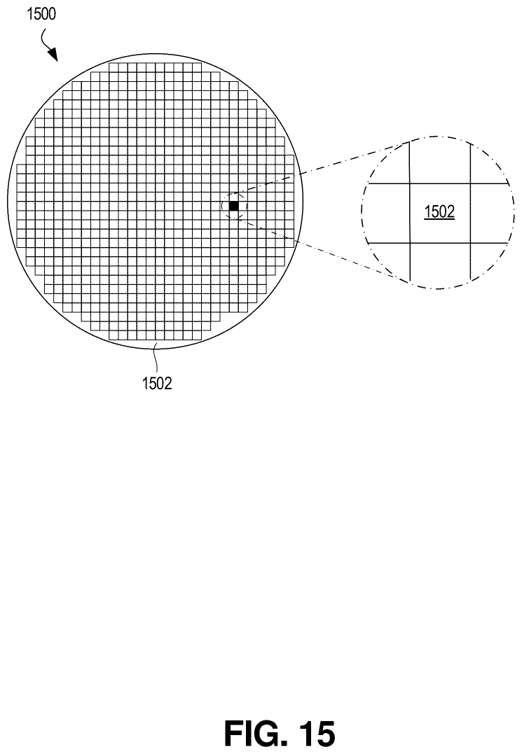

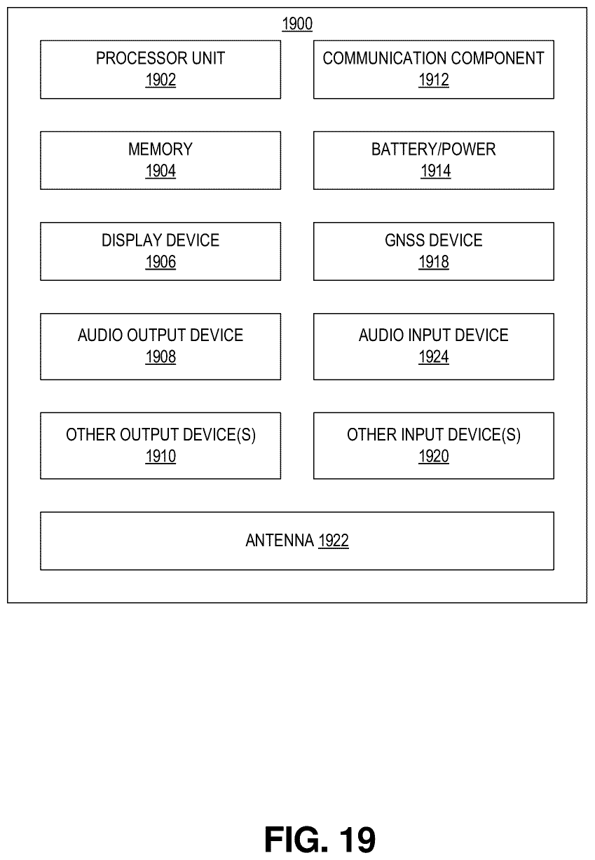

FIG. 15 is a top view of a wafer 1500 and dies 1502, wherein individual dies may include dies selectively transferred from donor wafers or dies integrated together in a system with such dies as disclosed herein. The wafer 1500 may be composed of semiconductor material and may include one or more dies 1502 having integrated circuit structures formed on a surface of the wafer 1500. The individual dies 1502 may be a repeating unit of an integrated circuit product that includes any suitable integrated circuit. After the fabrication of the semiconductor product is complete, the wafer 1500 may undergo a singulation process in which the dies 1502 are separated from one another to provide discrete “chips” of the integrated circuit product. The die 1502 may include one or more transistors, supporting circuitry to route electrical signals to the transistors, passive components (e.g., signal traces, resistors, capacitors, or inductors), and/or any other integrated circuit components. In some embodiments, the wafer 1500 or the die 1502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processor unit (e.g., the processor unit 1902 of FIG. 19) or other logic that is configured to store information in the memory devices or execute instructions stored in the memory array. In some embodiments, various ones of the microelectronic assemblies disclosed herein may be manufactured using a die-to-wafer assembly technique in which some dies are attached to a wafer 1500 that include other dies, and the wafer 1500 is subsequently singulated.

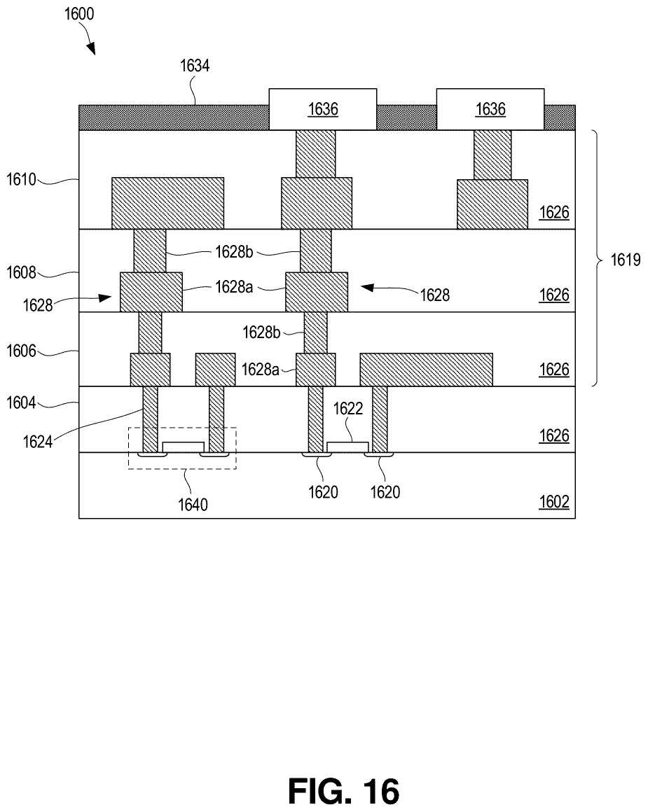

FIG. 16 is a cross-sectional side view of an integrated circuit device 1600 that may be included within IC components, such as dies, selectively transferred from donor wafers or circuitry incorporating such IC components as disclosed herein. One or more of the integrated circuit devices 1600 may be included in one or more dies 1502 (FIG. 15). The integrated circuit device 1600 may be formed on a die substrate 1602 (e.g., the wafer 1500 of FIG. 15) and may be included in a die (e.g., the die 1502 of FIG. 15). The die substrate 1602 may be a semiconductor substrate composed of semiconductor material systems including, for example, n-type or p-type materials systems (or a combination of both). The die substrate 1602 may include, for example, a crystalline substrate formed using a bulk silicon or a silicon-on-insulator (SOI) substructure. In some embodiments, the die substrate 1602 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1602. Although a few examples of materials from which the die substrate 1602 may be formed are described here, any material that may serve as a foundation for an integrated circuit device 1600 may be used. The die substrate 1602 may be part of a singulated die (e.g., the dies 1502 of FIG. 15) or a wafer (e.g., the wafer 1500 of FIG. 15).

The integrated circuit device 1600 may include one or more device layers 1604 disposed on the die substrate 1602. The device layer 1604 may include features of one or more transistors 1640 (e.g., metal oxide semiconductor field-effect transistors (MOSFETs)) formed on the die substrate 1602. The transistors 1640 may include, for example, one or more source and/or drain (S/D) regions 1620, a gate 1622 to control current flow between the S/D regions 1620, and one or more S/D contacts 1624 to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 16 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

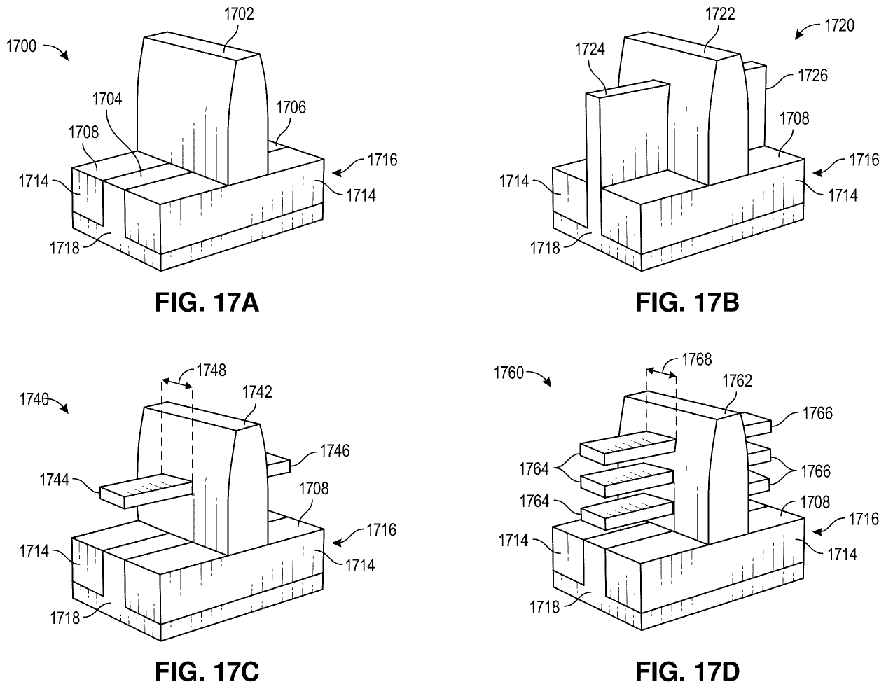

FIGS. 17A-17D are simplified perspective views of example planar, FinFET, gate-all-around, and stacked gate-all-around transistors. The transistors illustrated in FIGS. 17A-17D are formed on a substrate 1716 having a surface 1708. Isolation regions 1714 separate the source and drain regions of the transistors from other transistors and from a bulk region 1718 of the substrate 1716.

FIG. 17A is a perspective view of an example planar transistor 1700 comprising a gate 1702 that controls current flow between a source region 1704 and a drain region 1706. The transistor 1700 is planar in that the source region 1704 and the drain region 1706 are planar with respect to the substrate surface 1708.

FIG. 17B is a perspective view of an example FinFET transistor 1720 comprising a gate 1722 that controls current flow between a source region 1724 and a drain region 1726. The transistor 1720 is non-planar in that the source region 1724 and the drain region 1726 comprise “fins” that extend upwards from the substrate surface 1728. As the gate 1722 encompasses three sides of the semiconductor fin that extends from the source region 1724 to the drain region 1726, the transistor 1720 can be considered a tri-gate transistor. FIG. 17B illustrates one S/D fin extending through the gate 1722, but multiple S/D fins can extend through the gate of a FinFET transistor.

FIG. 17C is a perspective view of a gate-all-around (GAA) transistor 1740 comprising a gate 1742 that controls current flow between a source region 1744 and a drain region 1746. The transistor 1740 is non-planar in that the source region 1744 and the drain region 1746 are elevated from the substrate surface 1728.

FIG. 17D is a perspective view of a GAA transistor 1760 comprising a gate 1762 that controls current flow between multiple elevated source regions 1764 and multiple elevated drain regions 1766. The transistor 1760 is a stacked GAA transistor as the gate controls the flow of current between multiple elevated S/D regions stacked on top of each other. The transistors 1740 and 1760 are considered gate-all-around transistors as the gates encompass all sides of the semiconductor portions that extends from the source regions to the drain regions. The transistors 1740 and 1760 can alternatively be referred to as nanowire, nanosheet, or nanoribbon transistors depending on the width (e.g., widths 1748 and 1768 of transistors 1740 and 1760, respectively) of the semiconductor portions extending through the gate.

Returning to FIG. 16, a transistor 1640 may include a gate 1622 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of or comprise a U-shaped structure that includes a bottom portion substantially parallel to the surface of the die substrate 1602 and two sidewall portions that are substantially perpendicular to the top surface of the die substrate 1602. In other embodiments, at least one of the metal layers that form the gate electrode may simply be a planar layer that is substantially parallel to the top surface of the die substrate 1602 and does not include sidewall portions substantially perpendicular to the top surface of the die substrate 1602. In other embodiments, the gate electrode may consist of or comprise a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the die substrate 1602 adjacent to the gate 1622 of individual transistors 1640. The S/D regions 1620 may be formed using an implantation/diffusion process or an etching/deposition process, for example. In the former process, dopants such as boron, aluminum, antimony, phosphorous, or arsenic may be ion-implanted into the die substrate 1602 to form the S/D regions 1620. An annealing process that activates the dopants and causes them to diffuse farther into the die substrate 1602 may follow the ion-implantation process. In the latter process, the die substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 16 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the integrated circuit device 1600.

The interconnect structures 1628 (e.g., lines) may be arranged within the interconnect layers 1606-1610 to route electrical signals according to a wide variety of designs; in particular, the arrangement is not limited to the particular configuration of interconnect structures 1628 depicted in FIG. 16. Although a particular number of interconnect layers 1606-1610 is depicted in FIG. 16, embodiments of the present disclosure include integrated circuit devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the die substrate 1602 upon which the device layer 1604 is formed. For example, the lines 1628a may route electrical signals in a direction in and out of the page and/or in a direction across the page. The vias 1628b may be arranged to route electrical signals in a direction of a plane that is substantially perpendicular to the surface of the die substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 16. In some embodiments, dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same. The device layer 1604 may include a dielectric material 1626 disposed between the transistors 1640 and a bottom layer of the metallization stack as well. The dielectric material 1626 included in the device layer 1604 may have a different composition than the dielectric material 1626 included in the interconnect layers 1606-1610; in other embodiments, the composition of the dielectric material 1626 in the device layer 1604 may be the same as a dielectric material 1626 included in any one of the interconnect layers 1606-1610.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604. The vias 1628b of the first interconnect layer 1606 may be coupled with the lines 1628a of a second interconnect layer 1608.

The second interconnect layer 1608 (referred to as Metal 2 or “M2”) may be formed directly on the first interconnect layer 1606. In some embodiments, the second interconnect layer 1608 may include via 1628b to couple the lines 1628 of the second interconnect layer 1608 with the lines 1628a of a third interconnect layer 1610. Although the lines 1628a and the vias 1628b are structurally delineated with a line within individual interconnect layers for the sake of clarity, the lines 1628a and the vias 1628b may be structurally and/or materially contiguous (e.g., simultaneously filled during a dual-damascene process) in some embodiments.

The third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the integrated circuit device 1600 (i.e., farther away from the device layer 1604) may be thicker that the interconnect layers that are lower in the metallization stack 1619, with lines 1628a and vias 1628b in the higher interconnect layers being thicker than those in the lower interconnect layers.

The integrated circuit device 1600 may include a solder resist material 1634 (e.g., polyimide or similar material) and one or more conductive contacts 1636 formed on the interconnect layers 1606-1610. In FIG. 16, the conductive contacts 1636 are illustrated as taking the form of bond pads. The conductive contacts 1636 may be electrically coupled with the interconnect structures 1628 and configured to route the electrical signals of the transistor(s) 1640 to external devices. For example, solder bonds may be formed on the one or more conductive contacts 1636 to mechanically and/or electrically couple an integrated circuit die including the integrated circuit device 1600 with another component (e.g., a printed circuit board). The integrated circuit device 1600 may include additional or alternate structures to route the electrical signals from the interconnect layers 1606-1610; for example, the conductive contacts 1636 may include other analogous features (e.g., posts) that route the electrical signals to external components.

In some embodiments in which the integrated circuit device 1600 is a double-sided die, the integrated circuit device 1600 may include another metallization stack (not shown) on the opposite side of the device layer(s) 1604. This metallization stack may include multiple interconnect layers as discussed above with reference to the interconnect layers 1606-1610, to provide conductive pathways (e.g., including conductive lines and vias) between the device layer(s) 1604 and additional conductive contacts (not shown) on the opposite side of the integrated circuit device 1600 from the conductive contacts 1636.

In other embodiments in which the integrated circuit device 1600 is a double-sided die, the integrated circuit device 1600 may include one or more through silicon vias (TSVs) through the die substrate 1602; these TSVs may make contact with the device layer(s) 1604, and may provide conductive pathways between the device layer(s) 1604 and additional conductive contacts (not shown) on the opposite side of the integrated circuit device 1600 from the conductive contacts 1636. In some embodiments, TSVs extending through the substrate can be used for routing power and ground signals from conductive contacts on the opposite side of the integrated circuit device 1600 from the conductive contacts 1636 to the transistors 1640 and any other components integrated into the integrated circuit device (e.g., die) 1600, and the metallization stack 1619 can be used to route I/O signals from the conductive contacts 1636 to transistors 1640 and any other components integrated into the integrated circuit device (e.g., die) 1600.

Multiple integrated circuit devices 1600 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

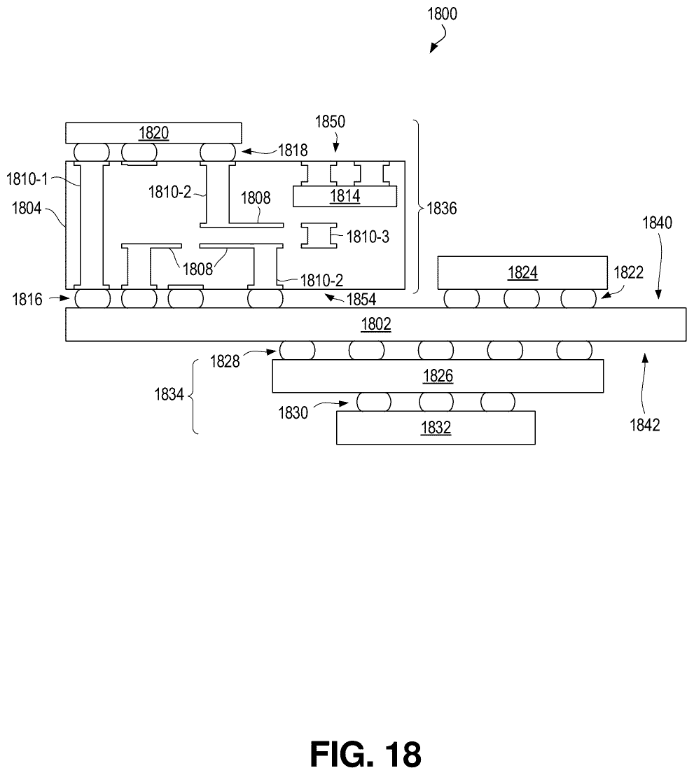

FIG. 18 is a cross-sectional side view of an integrated circuit device assembly 1800 that may include IC components, such as dies, selectively transferred from donor wafers as disclosed herein. In some embodiments, the integrated circuit device assembly 1800 may be a microelectronic assembly. The integrated circuit device assembly 1800 includes a number of components disposed on a circuit board 1802 (which may be a motherboard, system board, mainboard, etc.). The integrated circuit device assembly 1800 includes components disposed on a first face 1840 of the circuit board 1802 and an opposing second face 1842 of the circuit board 1802; generally, components may be disposed on one or both faces 1840 and 1842.

In some embodiments, the circuit board 1802 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1802. In other embodiments, the circuit board 1802 may be a non-PCB substrate. The integrated circuit device assembly 1800 illustrated in FIG. 18 includes a package-on-interposer structure 1836 coupled to the first face 1840 of the circuit board 1802 by coupling components 1816. The coupling components 1816 may electrically and mechanically couple the package-on-interposer structure 1836 to the circuit board 1802, and may include solder balls (as shown in FIG. 18), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1836 may include an integrated circuit component 1820 coupled to an interposer 1804 by coupling components 1818. The coupling components 1818 may take any suitable form for the application, such as the forms discussed above with reference to the coupling components 1816. Although a single integrated circuit component 1820 is shown in FIG. 18, multiple integrated circuit components may be coupled to the interposer 1804; indeed, additional interposers may be coupled to the interposer 1804. The interposer 1804 may provide an intervening substrate used to bridge the circuit board 1802 and the integrated circuit component 1820.

The integrated circuit component 1820 may be a packaged or unpackaged integrated circuit product that includes one or more integrated circuit dies (e.g., the die 1502 of FIG. 15, the integrated circuit device 1600 of FIG. 16) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1820, a single monolithic integrated circuit die comprises solder bumps attached to contacts on the die. The solder bumps allow the die to be directly attached to the interposer 1804. The integrated circuit component 1820 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1820 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1820 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1820 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1804 may spread connections to a wider pitch or reroute a connection to a different connection. For example, the interposer 1804 may couple the integrated circuit component 1820 to a set of ball grid array (BGA) conductive contacts of the coupling components 1816 for coupling to the circuit board 1802. In the embodiment illustrated in FIG. 18, the integrated circuit component 1820 and the circuit board 1802 are attached to opposing sides of the interposer 1804; in other embodiments, the integrated circuit component 1820 and the circuit board 1802 may be attached to a same side of the interposer 1804. In some embodiments, three or more components may be interconnected by way of the interposer 1804.

In some embodiments, the interposer 1804 may be formed as a PCB, including multiple metal layers separated from one another by layers of dielectric material and interconnected by electrically conductive vias. In some embodiments, the interposer 1804 may be formed of an epoxy resin, a fiberglass-reinforced epoxy resin, an epoxy resin with inorganic fillers, a ceramic material, or a polymer material such as polyimide. In some embodiments, the interposer 1804 may be formed of alternate rigid or flexible materials that may include the same materials described above for use in a semiconductor substrate, such as silicon, germanium, and other group III-V and group IV materials. The interposer 1804 may include metal interconnects 1808 and vias 1810, including but not limited to through hole vias 1810-1 (that extend from a first face 1850 of the interposer 1804 to a second face 1854 of the interposer 1804), blind vias 1810-2 (that extend from the first or second faces 1850 or 1854 of the interposer 1804 to an internal metal layer), and buried vias 1810-3 (that connect internal metal layers).

In some embodiments, the interposer 1804 can comprise a silicon interposer. Through silicon vias (TSV) extending through the silicon interposer can connect connections on a first face of a silicon interposer to an opposing second face of the silicon interposer. In some embodiments, an interposer 1804 comprising a silicon interposer can further comprise one or more routing layers to route connections on a first face of the interposer 1804 to an opposing second face of the interposer 1804.

The interposer 1804 may further include embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art.

The integrated circuit device assembly 1800 may include an integrated circuit component 1824 coupled to the first face 1840 of the circuit board 1802 by coupling components 1822. The coupling components 1822 may take the form of any of the embodiments discussed above with reference to the coupling components 1816, and the integrated circuit component 1824 may take the form of any of the embodiments discussed above with reference to the integrated circuit component 1820.

The integrated circuit device assembly 1800 illustrated in FIG. 18 includes a package-on-package structure 1834 coupled to the second face 1842 of the circuit board 1802 by coupling components 1828. The package-on-package structure 1834 may include an integrated circuit component 1826 and an integrated circuit component 1832 coupled together by coupling components 1830 such that the integrated circuit component 1826 is disposed between the circuit board 1802 and the integrated circuit component 1832. The coupling components 1828 and 1830 may take the form of any of the embodiments of the coupling components 1816 discussed above, and the integrated circuit components 1826 and 1832 may take the form of any of the embodiments of the integrated circuit component 1820 discussed above. The package-on-package structure 1834 may be configured in accordance with any of the package-on-package structures known in the art.

FIG. 19 is a block diagram of an example electrical device 1900 that may include IC components, such as dies, selectively transferred from donor wafers as disclosed herein. For example, any suitable components of the electrical device 1900 may include one or more of the integrated circuit device assemblies 1800, integrated circuit components 1820, integrated circuit devices 1600, integrated circuit dies 1502, or other components disclosed herein. A number of components are illustrated in FIG. 19 as included in the electrical device 1900, but any one or more of these components may be omitted or duplicated, as suitable for the application. In some embodiments, some or all of the components included in the electrical device 1900 may be attached to one or more motherboards mainboards, or system boards. In some embodiments, one or more of these components are fabricated onto a single system-on-a-chip (SoC) die.

Additionally, in various embodiments, the electrical device 1900 may not include one or more of the components illustrated in FIG. 19, but the electrical device 1900 may include interface circuitry for coupling to the one or more components. For example, the electrical device 1900 may not include a display device 1906, but may include display device interface circuitry (e.g., a connector and driver circuitry) to which a display device 1906 may be coupled. In another set of examples, the electrical device 1900 may not include an audio input device 1924 or an audio output device 1908, but may include audio input or output device interface circuitry (e.g., connectors and supporting circuitry) to which an audio input device 1924 or audio output device 1908 may be coupled.

The electrical device 1900 may include one or more processor units 1902 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1902 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1900 may include a memory 1904, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1904 may include memory that is located on the same integrated circuit die as the processor unit 1902. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1900 can comprise one or more processor units 1902 that are heterogeneous or asymmetric to another processor unit 1902 in the electrical device 1900. There can be a variety of differences between the processing units 1902 in a system in terms of a spectrum of metrics of merit including architectural, microarchitectural, thermal, power consumption characteristics, and the like. These differences can effectively manifest themselves as asymmetry and heterogeneity among the processor units 1902 in the electrical device 1900.

In some embodiments, the electrical device 1900 may include a communication component 1912 (e.g., one or more communication components). For example, the communication component 1912 can manage wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1912 may operate in accordance with other wireless protocols in other embodiments. The electrical device 1900 may include an antenna 1922 to facilitate wireless communications and/or to receive other wireless communications (such as amplitude modulation (AM) or frequency modulation (FM) radio transmissions).

In some embodiments, the communication component 1912 may manage wired communications, such as electrical, optical, or any other suitable communication protocols (e.g., IEEE 802.3 Ethernet standards). As noted above, the communication component 1912 may include multiple communication components. For instance, a first communication component 1912 may be dedicated to shorter-range wireless communications such as Wi-Fi or Bluetooth, and a second communication component 1912 may be dedicated to longer-range wireless communications such as global positioning system (GPS), EDGE, GPRS, CDMA, WiMAX, LTE, EV-DO, or others. In some embodiments, a first communication component 1912 may be dedicated to wireless communications, and a second communication component 1912 may be dedicated to wired communications.

The electrical device 1900 may include battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include a display device 1906 (or corresponding interface circuitry, as discussed above). The display device 1906 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1900 may include an audio output device 1908 (or corresponding interface circuitry, as discussed above). The audio output device 1908 may include any embedded or wired or wirelessly connected external device that generates an audible indicator, such speakers, headsets, or earbuds.

The electrical device 1900 may include an audio input device 1924 (or corresponding interface circuitry, as discussed above). The audio input device 1924 may include any embedded or wired or wirelessly connected device that generates a signal representative of a sound, such as microphones, microphone arrays, or digital instruments (e.g., instruments having a musical instrument digital interface (MIDI) output). The electrical device 1900 may include a Global Navigation Satellite System (GNSS) device 1918 (or corresponding interface circuitry, as discussed above), such as a Global Positioning System (GPS) device. The GNSS device 1918 may be in communication with a satellite-based system and may determine a geolocation of the electrical device 1900 based on information received from one or more GNSS satellites, as known in the art.

The electrical device 1900 may include an other output device 1910 (or corresponding interface circuitry, as discussed above). Examples of the other output device 1910 may include an audio codec, a video codec, a printer, a wired or wireless transmitter for providing information to other devices, or an additional storage device.

The electrical device 1900 may include an other input device 1920 (or corresponding interface circuitry, as discussed above). Examples of the other input device 1920 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2000 may be any other electronic device that processes data. In some embodiments, the electrical device 2000 may comprise multiple discrete physical components. Given the range of devices that the electrical device 2000 can be manifested as in various embodiments, in some embodiments, the electrical device 2000 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 10⁷ Siemens per meter (S/m) at 20 degrees Celsius. Examples of such materials include Cu, Ag, Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is adjacent to B” means that at least part of A is in direct physical contact with at least a part of B.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” in this context means there is only incidental variation. For example, composition that is substantially a first constituent means the composition may further include<1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a wafer comprising a base substrate; a first layer formed over the base substrate; a second layer formed over the first layer, wherein the second layer includes a plurality of integrated circuit (IC) dies and a bonding feature, wherein the plurality of IC dies and the bonding feature are to be released from the first layer when a portion of the wafer that includes the plurality of IC dies and the bonding feature is transferred to a second wafer.

Example 2 includes the subject matter of Example 1, and wherein the bonding feature is non-contiguous with the plurality of IC dies.

Example 3 includes the subject matter of any of Examples 1 and 2, and wherein the bonding feature is contiguous with two of the plurality of IC dies.

Example 4 includes the subject matter of any of Examples 1-3, and wherein the bonding feature comprises a strip extending from one edge of the wafer to another edge of the wafer.

Example 5 includes the subject matter of any of Examples 1-4, and wherein the bonding feature comprises a strip passing through a center point of the wafer.

Example 6 includes the subject matter of any of Examples 1-5, and wherein the wafer comprises a second bonding feature, wherein the bonding feature and the second bonding feature intersect and are orthogonal to each other.

Example 7 includes the subject matter of any of Examples 1-6, and wherein the wafer comprises a plurality of bonding features and a first IC die of the plurality of IC dies is in contact with at least two of the plurality of bonding features.

Example 8 includes the subject matter of any of Examples 1-7, and wherein the wafer comprises a plurality of bonding features, wherein at least some of the plurality of bonding features are in contact with respective pairs of the plurality of IC dies.

Example 9 includes the subject matter of any of Examples 1-8, and wherein the bonding feature is connected between corners of two IC dies of the plurality of IC dies.

Example 10 includes the subject matter of any of Examples 1-9, and wherein a first IC die of the plurality of IC dies has a chamfered corner and the bonding feature is proximate to the chamfered corner.

Example 11 includes an electronic device comprising an integrated circuit (IC) die; a stub extending from the IC die; and a mesa structure under the IC die and the stub, wherein the IC die and the stub are bonded to the mesa structure.

Example 12 includes the subject matter of Example 11, and wherein the IC die comprises a chamfered corner.

Example 13 includes the subject matter of any of Examples 11 and 12, and wherein the stub extends from a corner of the IC die.

Example 14 includes the subject matter of any of Examples 11-13, and wherein the IC die has a substantially rectilinear footprint and the stub extends orthogonally from a side of the IC die.

Example 15 includes the subject matter of any of Examples 11-14, and further including a printed circuit board coupled to the IC die.

Example 16 includes the subject matter of any of Examples 11-15, and further including a second IC die coupled to the printed circuit board.

Example 17 includes the subject matter of any of Examples 11-16, and further including a second stub extending from the IC die.

Example 18 includes the subject matter of any of Examples 11-17, and further including a second stub extending from the IC die in a direction opposite to a direction in which the stub extends from the IC die.

Example 19 includes the subject matter of any of Examples 11-18, and wherein the stub predominantly comprises silicon.

Example 20 includes the subject matter of any of Examples 11-19, and wherein the IC die comprises at least one chamfered corner.

Example 21 includes a method, comprising receiving a first substrate comprising a first integrated circuit (IC) component, a second IC component, and a tether connected between the first IC and the second IC, wherein the first IC component, second IC component, and tether are bonded to the first substrate over a mesa structure; and singulating the first IC and the second IC, wherein singulating the first IC and the second IC comprises removing at least a portion of the tether.

Example 22 includes the subject matter of Example 21, and wherein the first IC comprises a chamfered corner.

Example 23 includes the subject matter of any of Examples 21 and 22, and wherein the tether predominantly comprises silicon.

Example 24 includes the subject matter of any of Examples 21-23, and wherein the tether connects to corners of the first IC die and the second IC die.

Example 25 includes the subject matter of any of Examples 21-24, and wherein the first IC die has a substantially rectilinear footprint and the tether extends orthogonally from a side of the first IC die.

Example 26 includes the subject matter of any of Examples 21-25, and further including coupling a printed circuit board coupled to the first IC die.

Example 27 includes the subject matter of any of Examples 21-26, and further including coupling a third IC die coupled to the printed circuit board.

Example 28 includes the subject matter of any of Examples 21-27, and further including a second tether extending from the first IC die.

Example 29 includes the subject matter of any of Examples 21-28, and further including a second tether extending from the first IC die in a direction opposite to a direction in which the tether extends from the IC die.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. A wafer comprising:
a base substrate;
a first layer formed over the base substrate;
a second layer formed over the first layer, wherein the second layer includes a plurality of integrated circuit (IC) dies and a bonding feature, wherein the plurality of IC dies and the bonding feature are to be released from the first layer when a portion of the wafer that includes the plurality of IC dies and the bonding feature is transferred to a second wafer.

2. The wafer of claim 1, wherein the bonding feature is non-contiguous with the plurality of IC dies.

3. The wafer of claim 1, wherein the bonding feature is contiguous with two of the plurality of IC dies.

4. The wafer of claim 1, wherein the bonding feature comprises a strip extending from one edge of the wafer to another edge of the wafer.

5. The wafer of claim 1, wherein the bonding feature comprises a strip passing through a center point of the wafer.

6. The wafer of claim 1, wherein the wafer comprises a second bonding feature, wherein the bonding feature and the second bonding feature intersect and are orthogonal to each other.

7. The wafer of claim 1, wherein the wafer comprises a plurality of bonding features and a first IC die of the plurality of IC dies is in contact with at least two of the plurality of bonding features.

8. The wafer of claim 1, wherein the wafer comprises a plurality of bonding features, wherein at least some of the plurality of bonding features are in contact with respective pairs of the plurality of IC dies.

9. The wafer of claim 1, wherein the bonding feature is connected between corners of two IC dies of the plurality of IC dies.

10. The wafer of claim 1, wherein a first IC die of the plurality of IC dies has a chamfered corner and the bonding feature is proximate to the chamfered corner.

11. An electronic device comprising:
an integrated circuit (IC) die;
a stub extending from the IC die; and
a mesa structure under the IC die and the stub, wherein the IC die and the stub are bonded to the mesa structure.

12. The electronic device of claim 11, wherein the IC die comprises a chamfered corner.

13. The electronic device of claim 11, wherein the stub extends from a corner of the IC die.

14. The electronic device of claim 11, wherein the IC die has a substantially rectilinear footprint and the stub extends orthogonally from a side of the IC die.

15. The electronic device of claim 11, further comprising a printed circuit board coupled to the IC die.

16. The electronic device of claim 15, further comprising a second IC die coupled to the printed circuit board.

17. The electronic device of claim 11, further comprising a second stub extending from the IC die.

18. A method, comprising:
receiving a first substrate comprising a first integrated circuit (IC) die, a second IC die, and a tether connected between the first IC die and the second IC die, wherein the first IC die, second IC die, and tether are bonded to the first substrate over a mesa structure; and
singulating the first IC die and the second IC die, wherein singulating the first IC die and the second IC die comprises removing at least a portion of the tether.

19. The method of claim 18, wherein the first IC die comprises a chamfered corner.

20. The method of claim 18, wherein the tether predominantly comprises silicon.
